(19) United States
(12) Patent Application Publication
(10) Pub. No.: US 2019/0312050 A1
(43) Pub. Date: Oct. 10, 2019

(54) STRING SELECT LINE GATE OXIDE METHOD FOR 3D VERTICAL CHANNEL NAND MEMORY

(71) Applicant: MACRONIX INTERNATIONAL CO., LTD., HSINCHU (TW)

(72) Inventors: Erh-Kun LAI, TARRYTOWN, NY (US); Hsiang-Lan LUNG, Ardsley, NY (US)

(73) Assignee: MACRONIX INTERNATIONAL CO., LTD., HSINCHU (TW)

(21) Appl. No.: 15/950,021

(22) Filed: Apr. 10, 2018

(51) Int. Cl. H01L 27/11582; H01L 23/535; H01L 23/528; H01L 29/66

(52) U.S. Cl. CPC H01L 27/11582; H01L 29/66833; H01L 23/528; H01L 23/535

(57) ABSTRACT

A memory device includes a stack of conductive strips in a plurality of first levels with a first opening and a conductive strip in the second level with a second opening, both openings exposing sidewalls. Data storage structures are formed on the sidewalls of the conductive strips in the plurality of first levels. A first vertical channel structure including vertical channel films is disposed in the first opening, the vertical channel films in contact with the data storage structures. The second opening is aligned with the first vertical channel structure. A gate dielectric layer is disposed on the sidewall of the conductive strip in the second level. A second vertical channel structure including vertical channel films is disposed in the second opening in contact with the gate dielectric layer on the sidewall of the conductive strip in the second level.

### BACKGROUND

### Field of the Invention

The present invention relates to high density memory devices, and particularly to memory devices in which multiple planes of memory cells are arranged to provide a three-dimensional 3D array.

### Description of Related Art

As critical dimensions of devices in integrated circuits shrink to the limits of common memory cell technologies, designers have been looking for techniques to stack multiple planes of memory cells to achieve greater storage capacity, and to achieve lower costs per bit. For example, thin-film switch techniques are applied to charge trapping memory technologies in Lai., “A Multi-Layer Stackable Thin-Film Switch (TFT) NAND-Type Flash Memory,” IEEE Int'l Electron Devices Meeting, 11-13 Dec. 2006; and in Jung, “Three Dimensionally Stacked NAND Flash Memory Technology Using Stacking Single Crystal Si Layers on ILD and TANOS Structure for Beyond 30 nm Node,” IEEE Int'l Electron Devices Meeting, 11-13 Dec. 2006.

Another structure that provides vertical NAND cells in a charge trapping memory technology is described in Katsumata,., “Pipe-shaped BiCS Flash Memory ith 16 Stacked Layers and Multi-Level-Cell Operation for Ultra High Density Storage Devices,” 2009 Symposium on VLSI Technology Digest of Technical Papers, 2009. The structure described in Katsumata. includes a vertical NAND gate, using silicon-oxide-nitride-oxide-silicon SONOS charge trapping technology to create a storage site at each gate/vertical channel interface. The memory structure is based on a column of semiconductor material arranged as the vertical channel for the NAND gate, with a lower select gate adjacent the substrate, and an upper select gate on top. A plurality of horizontal word lines is formed using planar word line layers that intersect with the columns, forming a so-called gate-all-around the cell at each layer.

In another 3D NAND flash memory technology, NAND memory cells can be arranged along a vertical channel structure, with memory cells on opposing sides of the structure. In some embodiments, the vertical channel structure may be U-shaped semiconductor thin-film where a string of NAND cells extends down one side and up the other side of a single vertical channel structure as described in U.S. Pat. No. 9,524,980, issued 20 Dec. 2016, which is incorporated by reference as if fully set forth herein. The vertical channel structures are disposed between stacks of conductive strips operable as word lines with memory elements in between. As a result of these vertical channel structures, two memory cells are formed per frustum of the active pillar, where each memory cell at the frustum includes a channel on one side in the vertical channel structure. In alternative approaches, vertical channel structures can support even and odd NAND strings on opposing sides of each vertical channel structure.

In the 3D NAND flash memory described above, string select switches and reference select switches are disposed at interface regions between a top plane of conductive strips (., String Select Lines or SSLs) in the stacks and the vertical channel structure. In order to reliably control operations of the memory cells, it is desirable that the threshold voltages of string and reference select switches are stable. When string and reference select switches include charge storage structures as the memory cells, the switches can be charged such that their threshold voltage may vary. Therefore, additional circuitry may be required to program and erase the switches. In addition, the charge storage structures may be too thick for the string and reference select switches to control their channels adequately. See, for example, U.S. Pat. No. 9,559,113, entitled SSL/GSL GATE OXIDE IN 3D VERTICAL CHANNEL NAND, by Lai, which is incorporated by reference as if fully set forth herein.

It is therefore desirable to provide a 3D memory structure that provides string select switches and reference select switches with better ability to control their channel and stable threshold voltages, while memory cells are programmed or erased, without requiring additional circuitry to control the threshold voltages.

### SUMMARY

A 3D memory is described, which can be configured as a 3D NAND flash memory. The 3D memory comprises stacks of conductive strips separated by insulating material, including conductive strips in a plurality of first levels (Word Lines or WLs) and a conductive strip in a second level (String Select Lines or SSLs) over the conductive strips in the plurality of first levels. A first opening, such as a trench or a hole through the conductive strips in the plurality of first levels, exposes sidewalls of conductive strips on both sides of the first opening. Data storage structures are disposed on the sidewalls of one or both sides of the first opening and are adjacent the conductive strips in the plurality of first levels. A first vertical channel structure comprising one or more vertical channel films is disposed vertically in contact with the data storage structures on one or both sides of the first opening. A second opening through the conductive strip in the second level and aligned with the first vertical channel structure exposes sidewalls of the conductive strip on both sides of the second opening. The second opening may be a hole or a trench. A gate dielectric layer is disposed on the sidewalls of the conductive strip in the second level. A second vertical channel structure comprising one or more vertical channel films is disposed vertically in contact with the gate dielectric layers on one or both sides of the second opening. The gate dielectric layer and the second vertical channel structure enable the string select switches in the 3D memory to have better control of their channel and to maintain stable threshold voltages while memory cells are programmed or erased.

In some embodiments of the 3D memory device with first and second vertical channel structures, a first pad connects the first vertical channel structure to the second vertical channel structure. The first pad is connected with the vertical channel films of the first vertical channel structure and the vertical channel films of the second vertical channel structure. In some embodiments of the 3D memory device, the first pad is disposed inside the first opening and comprises an upper planarized surface in contact with the second vertical channel structure configured as a landing area for formation of the second vertical channel structure in electrical series with the first vertical channel structure.

In some embodiments of the 3D memory device with first and second vertical channel structures, a second pad is disposed inside the second opening and comprises an upper planarized surface in contact with an interlayer connector providing a current path to overlying patterned conductors acting as bit lines, and configured as a landing area for formation of the interlayer connector in electrical series with the second vertical channel structure.

In some embodiments of the 3D memory device with first and second vertical channel structures, the conductive strip in the second level may be thicker than the conductive strips in a plurality of first levels. In some embodiments of the 3D memory device with first and second vertical channel structures, the conductive strip in the second level may comprise a material different than the material in the conductive strips in the plurality of first levels.

In some embodiments of the 3D memory device with first and second vertical channel structures, the data storage structures may comprise a multilayer dielectric charge trapping structure. In some embodiments of the 3D memory device with first and second vertical channel structures, the gate dielectric layers in the second opening have a smaller effective oxide thickness than that of the data storage structures. The effective oxide thickness (EOT) is a thickness of the dielectric material normalized according to a ratio of the dielectric constant of silicon dioxide and the dielectric constant of the chosen dielectric material. In some embodiments of the 3D memory device with first and second vertical channel structures, the width of the second vertical channel structure is less than the width of the first vertical channel structure.

Methods for manufacturing 3D memory devices with first and second vertical channel structures as described herein are also provided.

Other aspects and advantages of the present invention can be seen on review of the drawings, the detailed description, and the claims, which follow.

### BRIEF DESCRIPTION OF THE DRAWINGS

FIGS. 1A, 1B, 1C, and 1D include a cross-sectional diagram of a 3D memory device with a first vertical channel structure and a second vertical channel structure, an isolation view of the first vertical channel structure and an isolation view of the second vertical channel structure, according to an embodiment of the present invention.

FIGS. 2A, 2B, 2C, and 2D include a cross-sectional diagram of a 3D memory device with a first vertical channel structure and a second vertical channel structure, an isolation view of the first vertical channel structure and an isolation view of the second vertical channel structure, according to an alternative embodiment of the present invention.

FIGS. 3-12 illustrate stages of an example process flow for manufacturing a memory device with a first vertical channel structure and a second vertical channel structure.

FIGS. 13-28 illustrate stages of an alternative example process flow for manufacturing a memory device with a first vertical channel structure and a second vertical channel structure.

FIG. 29 is a flowchart illustrating a method for manufacturing a memory device with a first vertical channel structure and a second vertical channel structure.

FIG. 30 is a simplified block diagram of an integrated circuit according to an embodiment of the present invention.

### DETAILED DESCRIPTION

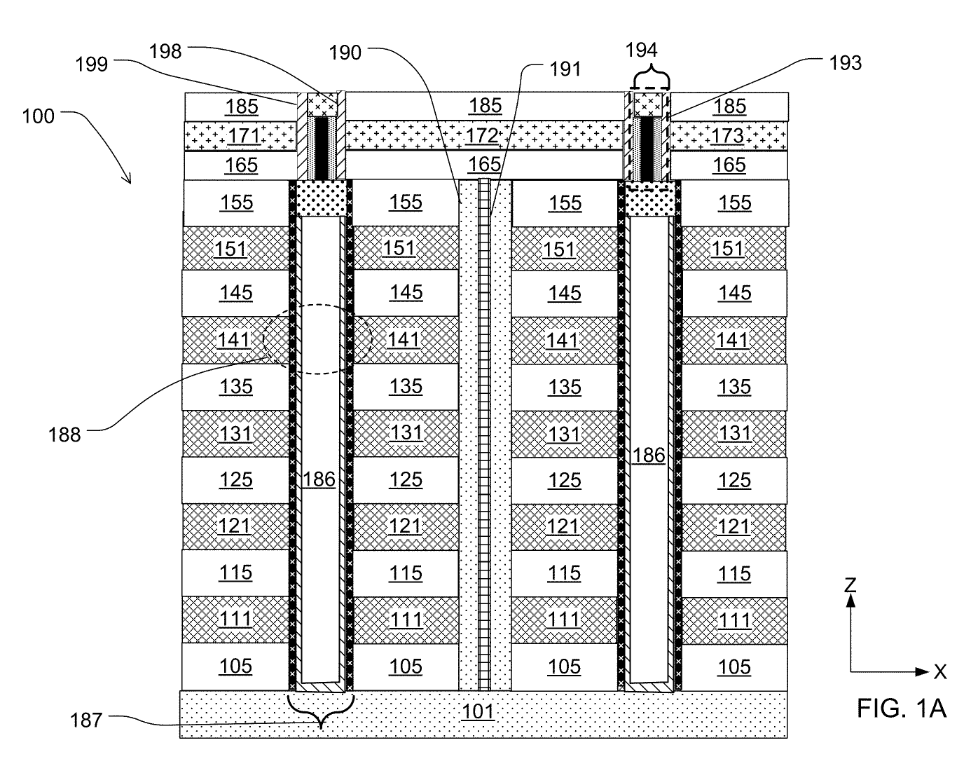

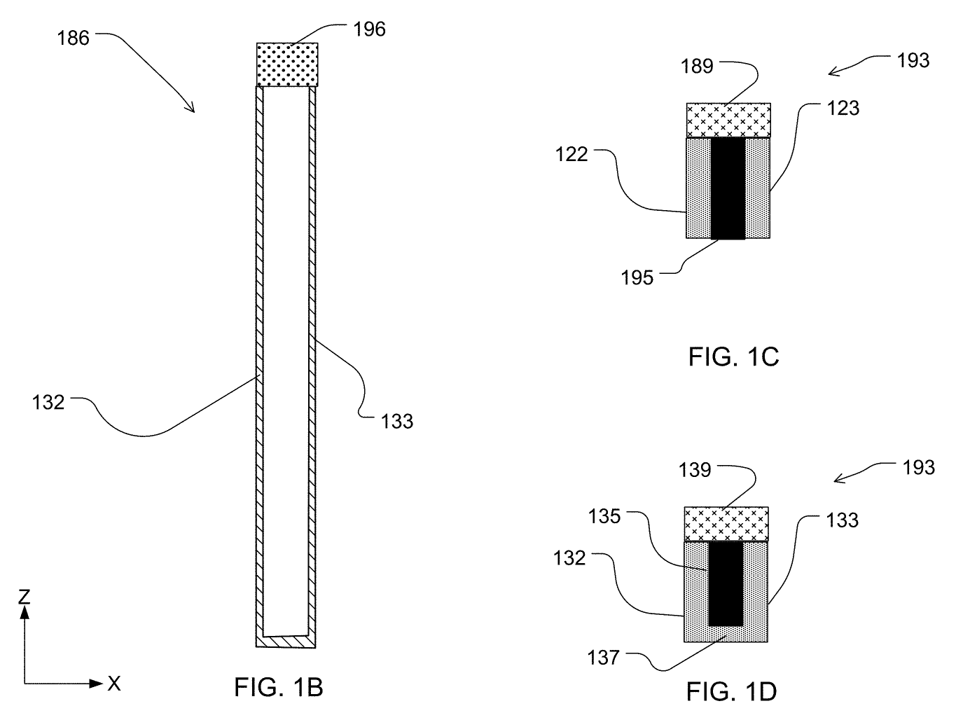

A detailed description of embodiments of the present invention is provided with reference to the FIGS. 1-30. The following description will typically be with reference to specific structural embodiments and methods. It is to be understood that there is no intention to limit the invention to the specifically disclosed embodiments and methods but that the invention may be practiced using other features, elements, methods, and embodiments. Preferred embodiments are described to illustrate the present invention, not to limit its scope, which is defined by the claims. Those of ordinary skill in the art will recognize a variety of equivalent variations on the description that follows.

FIG. 1A is a cross-sectional diagram of a 3D memory device 100 according to an embodiment of the present invention, shown in an X-Z plane. As illustrated in the example of FIG. 1A, a memory device 100 includes an array of NAND strings of memory cells formed over a conductive well in substrate 101. The device includes a plurality of stacks of conductive strips, each stack including conductive strips in a plurality of first levels 111, 121, 131, 141, 151 separated by insulating strips 105, 115, 125, 135, 145, 155. The conductive strips in a plurality of first levels 111, 121, 131, 141, 151 can be used as word lines or WLs. The conductive strips in a plurality of first levels may also include a bottom level or levels 111 of conductive strips which can be used as reference (e.g. ground) select lines (GSLs) or as assist gate lines (AG) in embodiments with U-shaped NAND strings. Each stack further includes conductive strips in a second level 171, 172, 173 (string select lines SSLs) between two insulating strips 165, 185. In embodiments with U-shaped NAND strings conductive strips in the second level can be used as reference (e.g. ground) select lines (GSLs). The conductive strips acting as word lines, string select lines, ground select lines and assist gate lines can comprise a variety of materials including doped semiconductors, metals, and conductive compounds, including materials comprising Si, Ge, SiGe, SiC, TiN, TaN, W, and Pt. In some embodiments, the conductive strips in the second level (GSLs, SSLs) may be thicker than the conductive strips (WLs) in a plurality of first levels. In some embodiments, the conductive strip in the second level may comprise a material different than the materials of the conductive strips in the plurality of first levels.

A first vertical channel structure 186 is disposed in the first opening 187 between the stacks, and can comprise semiconductor materials adapted to act as channels for the memory cells. FIG. 1B is a cross-sectional diagram of the semiconductor layer lining the opening in the first levels of conductive strips of first vertical channel structure 186 in FIG. 1A as shown in an X-Z plane. The first vertical channel structure may include a cylindrical vertical channel film including sides 132, 133 shown in the cross-section. In some embodiments, the vertical channel film may be electrically connected in the lower region of the first vertical channel structure 186. The first vertical channel structure 186 in this example includes a first pad 196. The first pad 196 is connected to the vertical channel film in the upper region of the first vertical channel structure. The vertical channel film can comprise semiconductor materials adapted to act as channels for the memory cells, such materials as Si, Ge, SiGe, GaAs, SiC, and graphene. The first pad 196 can comprise semiconductor materials, such as Si, polysilicon, Ge, SiGe, GaAs, and SiC, or other conductive materials such as silicides and metals. In some embodiments, the first vertical channel structure is cylindrical, and the conductive strips act as a gate-all-around structure surrounding the first vertical channel structure in each frustum of the first vertical channel structure. In some embodiments, the first vertical channel structure is formed in a trench, and the vertical channel film sides provide channel regions for separate NAND cells on opposing sides of the trench, and the conductive strips act as even and odd word lines for even and odd cells in each frustum of the first vertical channel structure.

Referring back to FIG. 1A, the memory device includes memory layers, such as data storage structures, in interface regions at cross-points 188 between side surfaces of the conductive strips in the plurality of first levels (WLs) in the stacks and the vertical channel structure 186. The memory layer can include a multilayer data storage structure, known from flash memory technologies, including, for example, flash memory technologies known as ONO (oxide-nitride-oxide), ONONO (oxide-nitride-oxide-nitride-oxide), SONOS (silicon-oxide-nitride-oxide-silicon), BE-SONOS (bandgap engineered silicon-oxide-nitride-oxide-silicon), TANOS (tantalum nitride, aluminum oxide, silicon nitride, silicon oxide, silicon), and MA BE-SONOS (metal-high-k bandgap-engineered silicon-oxide-nitride-oxide-silicon).

In a representative device, the dielectric layer of memory material can include a bandgap engineered composite tunneling dielectric layer comprising a layer of silicon dioxide less than 2 nm thick, a layer of silicon nitride less than 3 nm thick, and a layer of silicon dioxide less than 4 nm thick. In one embodiment, the composite tunneling dielectric layer consists of an ultrathin silicon oxide layer O₁ (e.g., <=15 Å), an ultrathin silicon nitride layer N₁ (e.g. <=30 Å) and an ultrathin silicon oxide layer O₂ (e.g. <=35 Å), which results in an increase in the valence band energy level of about 2.6 eV at an offset 15 Å or less from the interface with the semiconductor body. The O₂ layer separates the N₁ layer from the charge trapping layer, at a second offset (e.g., about 30 Å to 45 Å from the interface), by a region of lower valence band energy level (higher hole tunneling barrier) and higher conduction band energy level. The electric field sufficient to induce hole tunneling raises the valence band energy level after the second location to a level that effectively eliminates the hole tunneling barrier because the second location is at a greater distance from the interface. Therefore, the O₂ layer does not significantly interfere with the electric field assisted hole tunneling, while improving the ability of the engineered tunneling dielectric to block leakage during low fields. These layers can be conformally deposited using for example LPCVD. A charge trapping layer in the layer of memory material in one embodiment comprises silicon nitride having a thickness greater than 50 Å, including for example about 70 Å. Other charge trapping materials and structures may be employed, including for example silicon oxynitride (SiₓO_{y}N_{z}), silicon-rich nitride, silicon-rich oxide, trapping layers including embedded nano-particles and so on. The blocking dielectric layer of memory material in one embodiment comprises a layer of silicon dioxide having a thickness greater than 50 Å, including for example about 90 Å, and can be formed by LPCVD or another wet conversion from the nitride by a wet furnace oxidation process. Other blocking dielectrics can include high-κ materials like aluminum oxide.

In the illustrated example in FIG. 1A, the gate-all-around memory cells in the cross-points 188 of the stacks of conductive strips in the plurality of first levels or word lines are configured in a NAND string. The NAND string can be operated for read, erase and program operations.

In alternative embodiments, adjacent word lines in the stacks are connected to separate bias circuits (not shown), so that two charge storage sites at the frustum of each vertical channel structure between the adjacent word lines can be separately accessed and used for data storage. This arrangement of independent word lines can be implemented for example by connecting first stack word lines to a first bias structure, and second stack word lines to a separate bias structure.

A second opening 194, through the conductive strip in the second level 171 and aligned with the first pad in first vertical channel structure 186, exposes sidewalls of the conductive strip on both sides of the second opening 194. The second opening can have a smaller diameter than the first vertical channel structure. Gate dielectric layers 199, 198 are disposed on the sidewalls of the conductive strip in the second level 171. The gate dielectric layers 199, 198 may have a different material composition than the data storage structures 188, and can be chosen so that the SSL switch does not trap charge as do the memory layers. In some embodiments, the gate dielectric layer 199 may comprise a high dielectric constant material. The gate dielectric layers can include a layer of silicon oxide material thinner than the charge storage structures. In some embodiments, the gate dielectric layers 199, 198 in the second opening 194 may have a smaller effective oxide thickness than that of the data storage structures 188. The effective oxide thickness (EOT) is a thickness of the dielectric material normalized according to a ratio of the dielectric constant of silicon dioxide and the dielectric constant of the chosen dielectric material.

A second vertical channel structure 193 is disposed vertically in contact with the gate dielectric layers 199, 198 on one or both sides of the second opening 194, and in contact with the first pad.

FIG. 1C is a cross-sectional diagram of the second vertical channel structure 193 in FIG. 1A according to one embodiment as shown in an X-Z plane. The second vertical channel structure in FIG. 1C may include a cylindrical vertical channel film including sides 122, 123 shown in the cross-section, separated by an insulating column 195. The second vertical channel structure 193 may include a second pad 189. The second pad 189 is connected to the vertical channel film in the upper region of the second vertical channel structure 193. The vertical channel film can comprise semiconductor materials adapted to act as channels for the MOS transistor switches, such materials as Si, Ge, SiGe, GaAs, SiC, and graphene. The second pad 189 can comprise semiconductor materials, such as Si, polysilicon, Ge, SiGe, GaAs, and SiC, and other conducive compounds, such as silicides and metals.

FIG. 1D is a cross-sectional diagram of a second embodiment of the second vertical channel structure 193 in FIG. 1A. The second vertical channel structure in FIG. 1D may include a cylindrical vertical channel film including sides 132, 133 and bottom 137 as shown in the cross-section, the sides 132, 133 separated by an insulating column 135. The second vertical channel structure 193 may include a second pad 139. The second pad 139 is connected to the vertical channel film in the upper region of the second vertical channel structure 193. The vertical channel film can comprise semiconductor materials adapted to act as channels for the MOS transistor switches, such materials as Si, Ge, SiGe, GaAs, SiC, and graphene. The second pad 139 can comprise semiconductor materials, such as Si, polysilicon, Ge, SiGe, GaAs, and SiC, and other conducive compounds, such as silicides and metals.

In one embodiment, the conductive strip in the second level 171, 172, 173 may be a string select line (SSL) surrounding the second vertical channel structure to form a gate-all-around, vertical MOS transistor. A string select switch can be formed with the string select line (second level 171), the gate dielectric layer 199, and the second vertical channel structure 193. String select lines (SSL) and select switches formed with the gate dielectric layers 199, 198 and the second vertical channel structure 193 can operate at a lower voltage (e.g., 3.3 V) than the voltage required to operate memory cells formed with data storage structures.

Referring back to FIG. 1A, in some embodiments of the 3D memory device with first and second vertical channel structures, the width of the second vertical channel structure 193 is less than the width of the first vertical channel structure 186. The first pad 196 connects the first vertical channel structure 186 to the second vertical channel structure 193. The first pad 196 is connected with the vertical channel films sides 132, 133 of the first vertical channel structure 186 and the vertical channel films sides 122, 123 of the second vertical channel structure 193. In some embodiments, the first pad 196 may comprise an upper planarized surface in contact with the second vertical channel structure 193.

The memory device in FIG. 1A includes a source line 191 separated from the two first vertical channel structures 186 by insulating layers 190 and connected to the conducting substrate 101. The memory device can include an overlying patterned conductive layer (not shown) connected to the second vertical channel structure 193, including a plurality of global bit lines coupled to sensing circuits.

Therefore, 3D memory devices with first and second vertical channel structures are disclosed, each vertical channel structure including one or more vertical channel films. The gate dielectric layers 199, 198 and the second vertical channel structure 193 enable the string select switches and the ground select switches, comprising the conductive strip in the second level 171, 172, 173 as its gate, to have better control of their channel, i.e., vertical channel film of the second vertical channel structure 193, and to maintain stable threshold voltages while memory cells are programmed or erased.

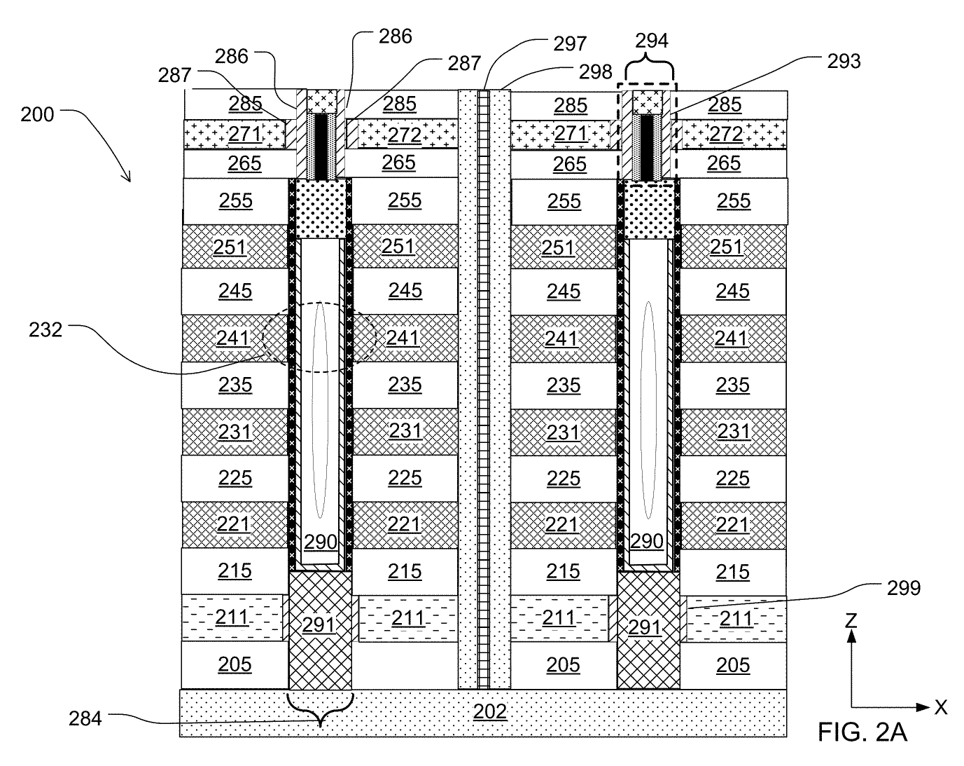

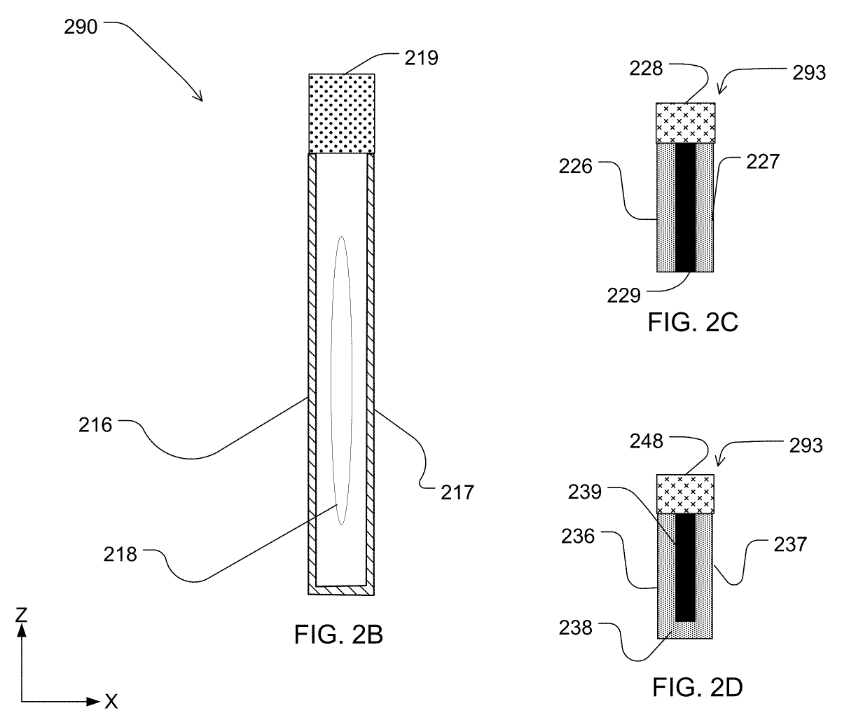

The technology can be utilized in other 3D memory devices as well. FIG. 2A is a cross-sectional diagram of a 3D memory device 200 according to an alternate embodiment of the present invention, shown in an X-Z plane. As illustrated in FIG. 2A, a memory device 200 includes an array of NAND strings of memory cells formed over a conductive well in substrate 202. The device includes a plurality of stacks of conductive strips, each stack including conductive strips in a plurality of first levels 211, 221, 231, 241, 251 separated by insulating strips 205, 215, 225, 235, 245, 255. The conductive strips in a plurality of first levels include a plurality of first levels 211, 221, 231, 241, 251 of conductive strips which can be used as word lines or WLs. The conductive strips in a plurality of first levels may also include a bottom level or levels 211 of conductive strips which can be used as reference (e.g. ground) select lines (GSLs) or as assist gate lines (AG) in embodiments with U-shaped NAND strings. Each stack further includes conductive strips in a second level 271, 272 (string select lines SSLs) between two insulating strips 265, 285. In embodiments with U-shaped NAND strings conductive strips in the second level can be used as reference (e.g. ground) select lines (GSLs). The conductive strips acting as word lines, string select lines, ground select lines and an assist gate can comprise a variety of materials including doped semiconductors, metals, and conductive compounds, including materials comprising Si, Ge, SiGe, SiC, TiN, TaN, W, and Pt. In some embodiments, the conductive strip in the second level (GSLs, SSLs) may be thicker than the conductive strips (WLs) in the plurality of first levels. In some embodiments, the conductive strip in the second level may comprise a material different than the material in the conductive strips in the plurality of first levels.

A first vertical channel structure 290 is disposed in the first opening 284 between the stacks, and can comprise semiconductor materials adapted to act as channels for the memory cells. FIG. 2B is a cross-sectional diagram of the first vertical channel structure 290 in FIG. 2A shown in an X-Z plane. The first vertical channel structure may include a cylindrical vertical channel film including sides 216, 217 shown in the cross-section. In some embodiments, the vertical channel film may be electrically connected in the lower region of the first vertical channel structure 290. The first vertical channel structure 186 may include a first pad 219. The first pad 219 is connected to the vertical channel film in the upper region of the first vertical channel structure. The vertical channel film can comprise semiconductor materials adapted to act as channels for the memory cells, such materials as Si, Ge, SiGe, GaAs, SiC, and graphene. The first pad 219 can comprise semiconductor materials, such as Si, polysilicon, Ge, SiGe, GaAs, and SiC. In one embodiment, an air gap 218 may be left at least in regions adjacent to the vertical channel film sides 216, 217. In some embodiments, a semiconductor pad 291 may be disposed in the second opening 294, below the first vertical channel structure 290. The semiconductor pad 291 can comprise semiconductor materials, such as Si, polysilicon, Ge, SiGe, GaAs, and SiC. In some embodiments, the conductive strips next to the semiconductor pad 291 may have a dielectric liner 299 on the sidewalls in contact with the semiconductor pad 291. In some embodiments, the dielectric liners 299 may be formed by surface oxidation of the semiconductor material of the semiconductor pad 291. The thickness of the dielectric liner can be in the range of 0.1 nm to 20 nm in some embodiments. Thicknesses in a range of 2 nm to 5 nm are preferred in some embodiments. In some embodiments, the dielectric liners 299 can comprise silicon nitride, which has a higher dielectric constant than silicon oxide, for example. Also, the dielectric liners 299 can comprise a different material than the material of insulating strips 205, 215, 225, 235, 245, 255. In some embodiments, the first vertical channel structure is cylindrical, and the conductive strips act as a gate-all-around structure surrounding the first vertical channel structure in each frustum of the first vertical channel structure. In some embodiments, the first vertical channel structure is formed in a trench, and the first vertical channel film and second vertical channel film provide channel regions for separate NAND cells on opposing sides of the trench, and the conductive strips act as even and odd word lines for even and odd cells in each frustum of the first vertical channel structure.

Referring back to FIG. 2A, the memory device includes memory layers, such as data storage structures, in interface regions at cross-points 232 between side surfaces of the conductive strips in the plurality of first levels (WLs) in the stacks and the first vertical channel structure 290. The memory layer can include a multilayer data storage structure, known from flash memory technologies, including for example flash memory technologies known as ONO (oxide-nitride-oxide), ONONO (oxide-nitride-oxide-nitride-oxide), SONOS (silicon-oxide-nitride-oxide-silicon), BE-SONOS (bandgap engineered silicon-oxide-nitride-oxide-silicon), TANOS (tantalum nitride, aluminum oxide, silicon nitride, silicon oxide, silicon), and MA BE-SONOS (metal-high-k bandgap-engineered silicon-oxide-nitride-oxide-silicon). The outer surfaces of the multilayer data storage structures contact the dielectric liners of the conductive strips.

In a representative device, the dielectric layer of memory material can include a bandgap engineered composite tunneling dielectric layer comprising a layer of silicon dioxide less than 2 nm thick, a layer of silicon nitride less than 3 nm thick, and a layer of silicon dioxide less than 4 nm thick. In one embodiment, the composite tunneling dielectric layer consists of an ultrathin silicon oxide layer O₁ (e.g., <=15 Å), an ultrathin silicon nitride layer N₁ (e.g. <=30 Å) and an ultrathin silicon oxide layer O₂ (e.g. <=35 Å), which results in an increase in the valence band energy level of about 2.6 eV at an offset 15 Å or less from the interface with the semiconductor body. The O₂ layer separates the N₁ layer from the charge trapping layer, at a second offset (e.g., about 30 Å to 45 Å from the interface), by a region of lower valence band energy level (higher hole tunneling barrier) and higher conduction band energy level. The electric field sufficient to induce hole tunneling raises the valence band energy level after the second location to a level that effectively eliminates the hole tunneling barrier because the second location is at a greater distance from the interface. Therefore, the O₂ layer does not significantly interfere with the electric field assisted hole tunneling, while improving the ability of the engineered tunneling dielectric to block leakage during low fields. These layers can be conformally deposited using for example LPCVD. A charge trapping layer in the layer of memory material in one embodiment comprises silicon nitride having a thickness greater than 50 Å, including for example about 70 Å. Other charge trapping materials and structures may be employed, including for example silicon oxynitride (SiₓO_{y}N_{z}), silicon-rich nitride, silicon-rich oxide, trapping layers including embedded nano-particles and so on. The blocking dielectric layer of memory material in one embodiment comprises a layer of silicon dioxide having a thickness greater than 50 Å, including for example about 90 Å, and can be formed by LPCVD or another wet conversion from the nitride by a wet furnace oxidation process. Other blocking dielectrics can include high-κ materials like aluminum oxide.

In the illustrated example in FIG. 2A, the memory cells in the cross-points 232 on the opposing sides of the stacks of conductive strips in the plurality of first levels or word lines are configured in a NAND string. The NAND string can be operated for read, erase and program operations.

In alternative embodiments, adjacent word lines in the stacks are connected to separate bias circuits (not shown), so that two charge storage sites at the frustum of each vertical channel structure between the adjacent word lines can be separately accessed and used for data storage. This arrangement of independent word lines can be implemented for example by connecting the first stack word lines to a first bias structure, and the second stack word lines to a separate bias structure.

A second opening 294 through the conductive strip in the second level 271, 272, and aligned with the first vertical channel structure 290, exposes sidewalls of the conductive strip on both sides of the second opening 294. In some embodiments, the conductive strips in the second level may have dielectric liners 287 on the sidewalls in contact with the gate dielectric layer 286. The thickness of the dielectric liner can be in the range of 0.1 nm to 20 nm in some embodiments. Thicknesses in a range of 2 nm to 5 nm are preferred in some embodiments.

Gate dielectric layers 286 are disposed on the sidewalls of the conductive strip in the second level 271. The gate dielectric layers 286 may have a different material composition than the data storage structures at cross-points 232 and cannot trap charges. In some embodiments, the gate dielectric layer 199 may comprise a high dielectric constant material. The gate dielectric layers can include a layer of silicon oxide material thinner than the charge storage structures. In some embodiments, the combination of the gate dielectric layers 286, and the dielectric liner 287 may have a smaller effective oxide thickness than that of the data storage structures at cross-points 232. The effective oxide thickness (EOT) is a thickness of the dielectric material normalized according to a ratio of the dielectric constant of silicon dioxide and the dielectric constant of the chosen dielectric material.

A second vertical channel structure 293 is disposed vertically in contact with the gate dielectric layers 286 on one or both sides of the second opening 294.

FIG. 2C is a cross-sectional diagram of the second vertical channel structure 293 in FIG. 2A according to one embodiment as shown in an X-Z plane. The second vertical channel structure includes a cylindrical vertical channel film including sides 226, 227 shown in the cross-section, separated by an insulating column 229. The second vertical channel structure 293 may include a second pad 228. The second pad 228 is connected to the vertical channel film in the upper region of the second vertical channel structure 293. The vertical channel can comprise semiconductor materials adapted to act as channels for the MOS transistor switches, such materials as Si, Ge, SiGe, GaAs, SiC, and graphene. The second pad 228 can comprise semiconductor materials, such as Si, polysilicon, Ge, SiGe, GaAs, and SiC, and other conducive compounds, such as silicides and metals.

FIG. 2D is a second embodiment of the second vertical channel structure 293 in FIG. 2A. The second vertical channel structure includes a cylindrical vertical channel film including sides 236, 237 and a bottom 238 as shown in the cross-section, the sides 236, 237 separated by an insulating column 239. The second vertical channel structure 293 may include a second pad 248. The second pad 248 is connected to the vertical channel film in the upper region of the second vertical channel structure 293. The vertical channel can comprise semiconductor materials adapted to act as channels for the MOS transistor switches, such materials as Si, Ge, SiGe, GaAs, SiC, and graphene. The second pad 248 can comprise semiconductor materials, such as Si, polysilicon, Ge, SiGe, GaAs, and SiC, and other conducive compounds, such as silicides and metals.

In one embodiment, the conductive strip in the second level 271, 272 may be a string select line (SSL) surrounding the second vertical channel structure to form a gate-all-around, vertical MOS transistor. A string select switch can be formed with the string select line in the second level 271, a dielectric liner 287, a gate dielectric layer 286, and the second vertical channel structure 293. The string select switches formed with the gate dielectric layers 286, dielectric liners 287 and the second vertical channel structure 293 cannot trap charges and thus have fixed threshold voltages.

Referring back to FIG. 2A, in some embodiments of the 3D memory device with first and second vertical channel structures, the width of the second vertical channel structure is less than the width of the first vertical channel structure. The first pad 219 connects the first vertical channel structure 290 to the second vertical channel structure 293. The first pad 219 is connected with the vertical channel films of the first vertical channel structure 290 and the vertical channel films of the second vertical channel structure 293. In some embodiments, the first pad 219 may comprise an upper planarized surface in contact with the second vertical channel structure 293.

The memory device in FIG. 2A includes a source line 297 separated from the two first vertical channel structures by insulating layers 298. The memory device can include an overlying patterned conductive layer (not shown) connected to the plurality of second vertical channel structures 293, including a plurality of global bit lines coupled to sensing circuits.

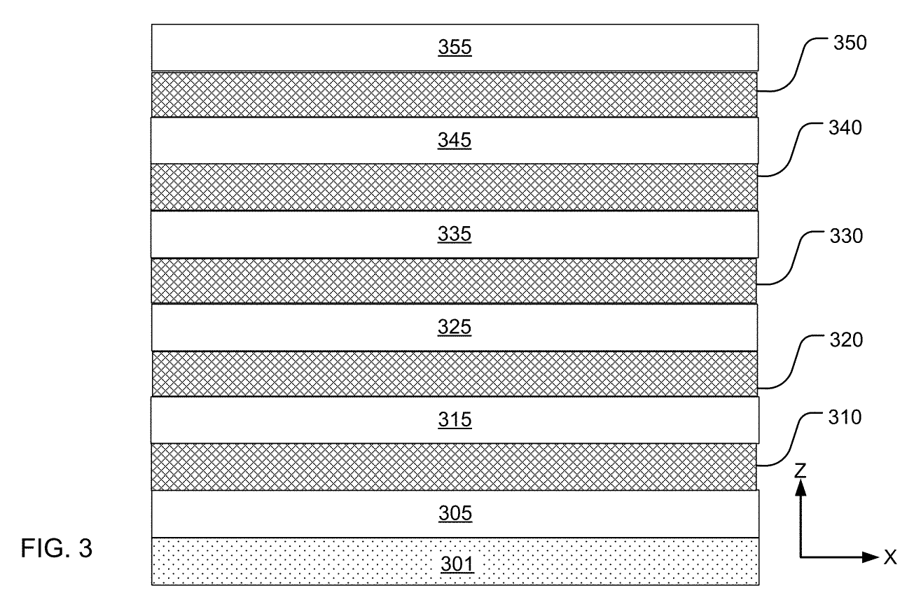

FIGS. 3 through 12 illustrate an example process flow for a 3D memory device with first and second vertical channel structures like that of FIGS. 1A, 1B, 1C.

FIG. 3 illustrates a stage of the process flow after forming a plurality of conductive layers on top of a conductive layer 301 which can comprise doped or undoped silicon or semiconducting material. To form the structure shown in FIG. 3, a plurality of first layers 310, 320, 330, 340, 350 of a first conductive material, such as doped polysilicon, or other material suitable for use as word lines, separated by layers of insulating material 305, 315, 325, 335, 345, 355, are disposed over the conductive layer 301. In embodiments described herein, the conductive material can be a heavily p-type doped polysilicon (P+ polysilicon) or other material selected for compatibility with the data storage structures. The layers of insulating material can comprise silicon dioxide deposited in a variety of ways as known in the art. Also, the layers of insulating material can comprise other insulating materials, and combinations of insulating materials. In this example, all of the insulating layers consist of the same material. In other examples, different materials can be used in different layers as suits a particular design goal. After the plurality of layers is formed, a patterned etch is applied to form a plurality of stacks of conductive strips and first openings.

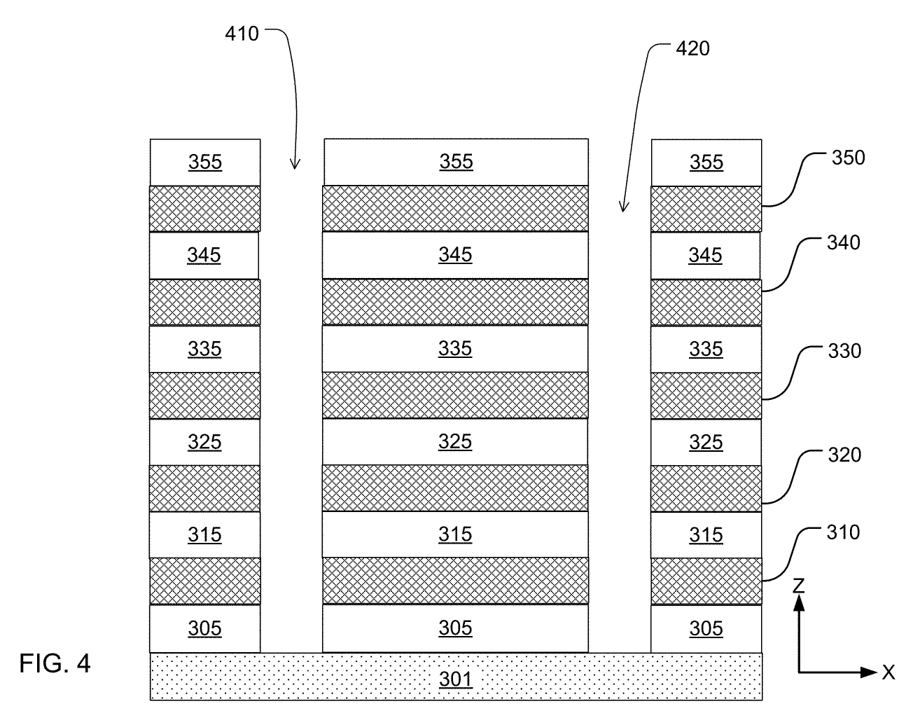

FIG. 4 illustrates a stage of the process after etching the plurality of layers, and stopping below the top surface of the conductive layer 301 to define a plurality of stacks of conductive strips. The stacks include conductive strips in a plurality of first levels 310, 320, 330, 340, 350. At least one of the conductive strips in a plurality of first levels can be used as WLs. The stacks include layers of insulating material 305, 315, 325, 335, 345, 355 separating the conductive strips from one another.

The etching process further defines first openings 410 and 420. The opening may be a trench or a hole. For the purpose of this application, a process flow is shown where the etching process defines one or more trenches. However, the technology disclosed herein can also be formed in a hole opening.

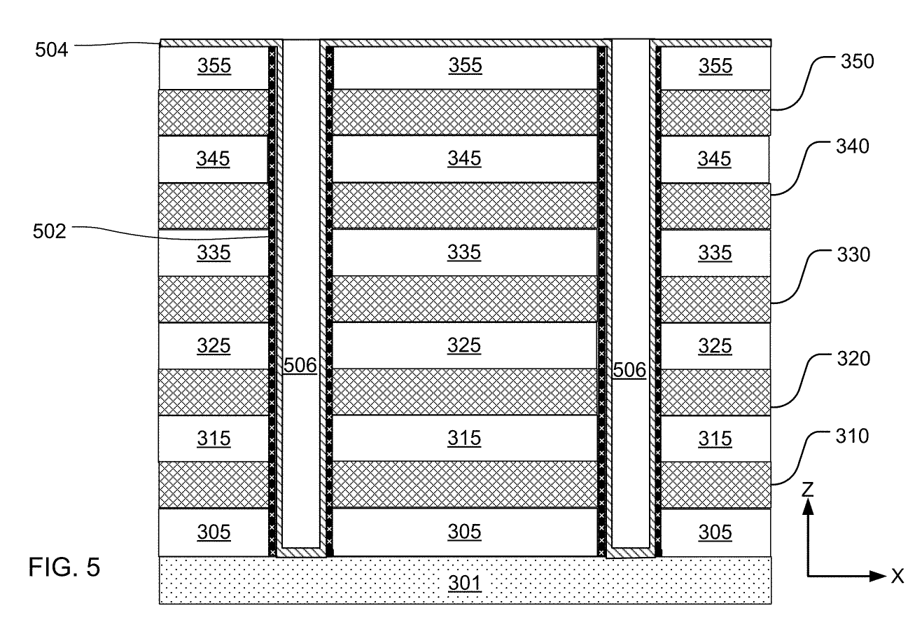

FIG. 5 illustrates a stage of the process flow after forming a memory layer 502 on sides of conductive strips in the plurality of stacks and a plurality of first vertical channel structures 506. The memory layer contacts side surfaces of the plurality of conductive strips. The memory layer can comprise a multilayer data storage structure including a tunneling layer, a charge storage layer, and a blocking layer, examples of which are discussed above. To form the memory layers on sides of conductive strips in the plurality of stacks, a memory structure is formed over and on sides of conductive strips in the plurality of stacks, and the parts of the memory structures over the stacks of conductive strips and the bottoms of the first openings are etched. To form the first vertical channel structures 506, a first semiconductor layer 504 is formed over the plurality of stacks and having a surface conformal with the memory layer 502. In the dielectric charge storage embodiment, the first semiconductor layer 504 contacts the memory layer 502 at least in the regions in which memory cells are being formed. The semiconductor material in the first semiconductor layer 504 comprises a semiconductor adapted by choice of material, e.g., silicon, and doping concentrations (e.g., undoped or lightly doped) to act as channel regions for vertical strings of memory cells, at least in the regions between the stacks so as to form channel films on the sidewalls of the opening. As illustrated in FIG. 5, in the regions between the stacks, the first semiconductor layer 504 extends to the bottoms of the openings between the stacks, and overlies the conductive layer 301. The first openings 410 and 420 are then filled with an insulating material, such as un-conformal silicon oxide to form first vertical channel structures 506. In some embodiments, the first vertical channel structures 506 are cylindrical, and the conductive strips act as gate-all-around structures surrounding the first vertical channel structures in each frustum of the first vertical channel structures. In some embodiments, the first vertical channel structures are formed in a trench, and the first vertical channel film and second vertical channel film provide channel regions for separate NAND cells on opposing sides of the trench, and the conductive strips act as even and odd word lines for even and odd cells in each frustum of the first vertical channel structures.

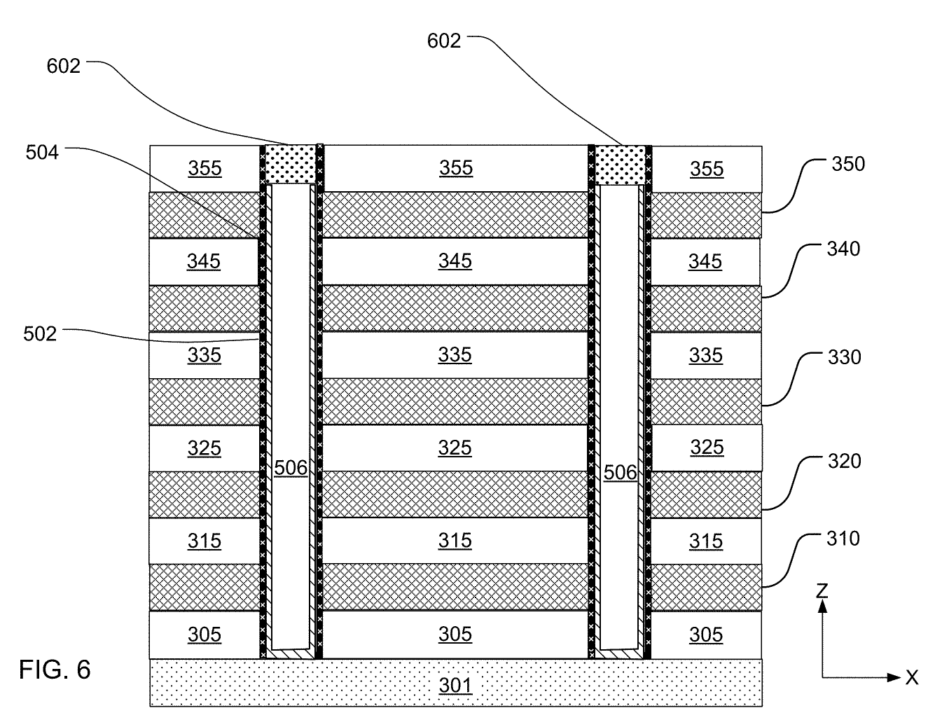

FIG. 6 illustrates a stage in the process flow after performing a step to form first pads 602. The first semiconductor layer 504 on top of the stacks is planarized, for instance using CMP (chemical-mechanical-planarization), stopping at an insulating material layer 355. As the un-conformal silicon oxide inside the first vertical channel structures is porous and has a higher etch rate than the etch rate of the layer 355 of insulating material, recesses are formed on top of the first vertical channel structures. A semiconductor material is deposited in the recesses and on top of the stacks. The deposited semiconductor material on top of the stacks is then planarized, for instance using CMP (chemical-mechanical-planarization), stopping at an insulating material layer 355. The recesses are still filled with semiconductor material after the second planarization and form the first pads 602. The first pads 602 can comprise semiconductor materials, such as Si, polysilicon, Ge, SiGe, GaAs, and SiC.

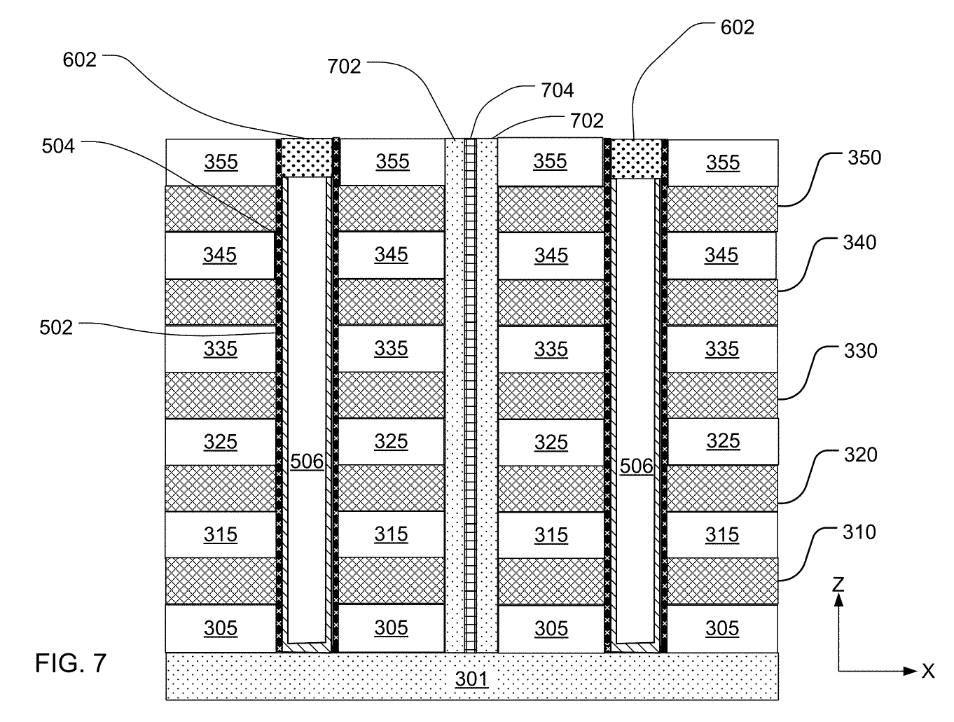

FIG. 7 illustrates a stage in the process flow after performing a step to form a source line 704 between the first vertical channel structures 506. The source line can comprise a variety of materials including doped semiconductors, metals, and conductive compounds, including materials comprising Si, Ge, SiGe, SiC, TiN, TaN, W, and Pt. The source line 704 is separated from the conductive strips in the plurality of first levels 310, 320, 330, 340, 350 by insulating layers 702. The source line 704 and insulating layers 702 may be formed by etching a first source line opening and then depositing an insulating material inside the first source line opening. A second source line opening is then etched in the deposited insulating material. The second source line opening is filled with a material selected for compatibility to form the source line 704.

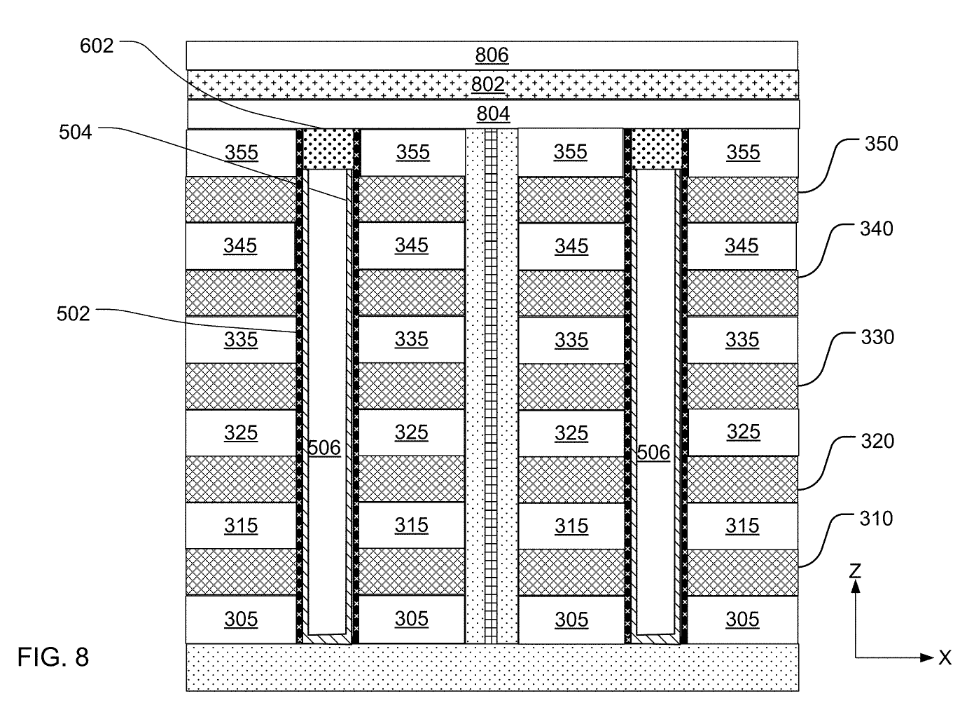

FIG. 8 illustrates a stage of the process flow after forming a conductive layer in the second level on top of the structure in FIG. 7. To form the structure shown in FIG. 8, a layer in the second level 802 of a second conductive material, such as doped polysilicon, or other material suitable for use as string select lines, separated by layers 804, 806 of insulating material, are disposed over the first vertical channel structures 506 and the conductive strips in the plurality of first levels 310, 320, 330, 340, 350. In some embodiments, the second conductive material can be a heavily p-type doped polysilicon (P+ polysilicon) or other material selected for compatibility. In some embodiments, the second conductive material may be different than the first conductive material, where the conductive strips in the plurality of first levels 310, 320, 330, 340, 350 are comprised of the first conductive material. The layers 804, 806 of insulating material can comprise silicon dioxide deposited in a variety of ways as known in the art. Also, the layers of insulating material can comprise other insulating materials, and combinations of insulating materials. In this example, all of the insulating layers consist of the same material. In other examples, different materials can be used in different layers as suits a particular design goal. A patterned etch is applied to form a plurality of conductive strips in the second level and second openings.

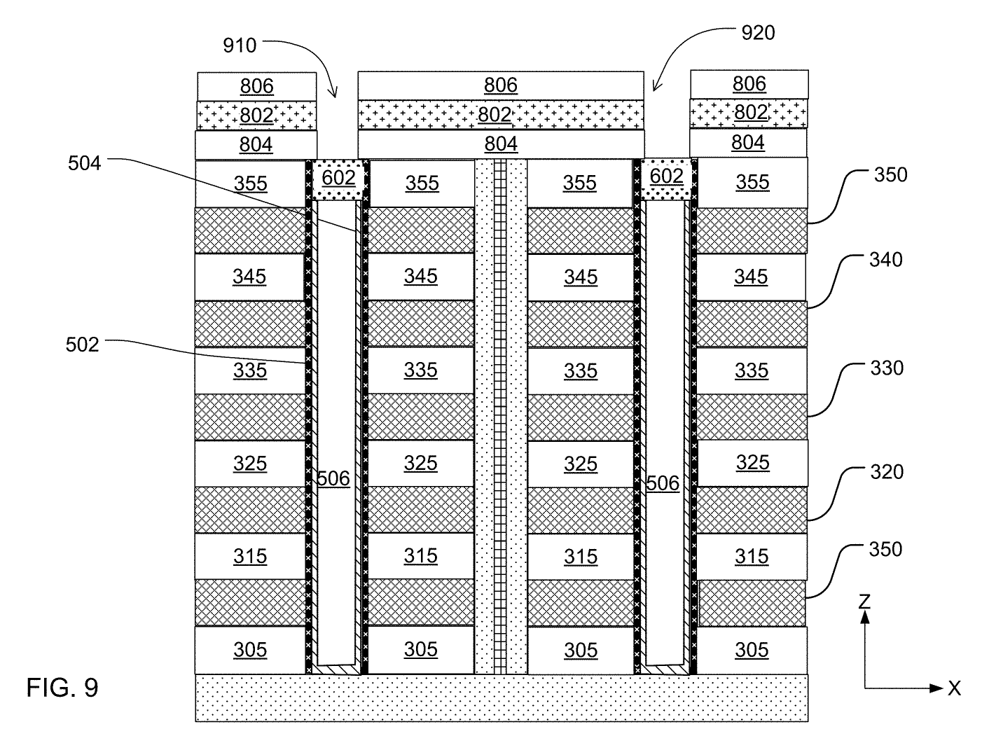

FIG. 9 illustrates a stage of the process after etching layers 802, 804, 806, and stopping below the top surface of the first pads 602 to define conductive strips in the second level 802. In some embodiments, the conductive strips in the second level 802 may be thicker than the conductive strips in a plurality of first levels 310, 320, 330, 340, 350. The etching process further defines second openings 910 and 920. The opening may be a trench or a hole.

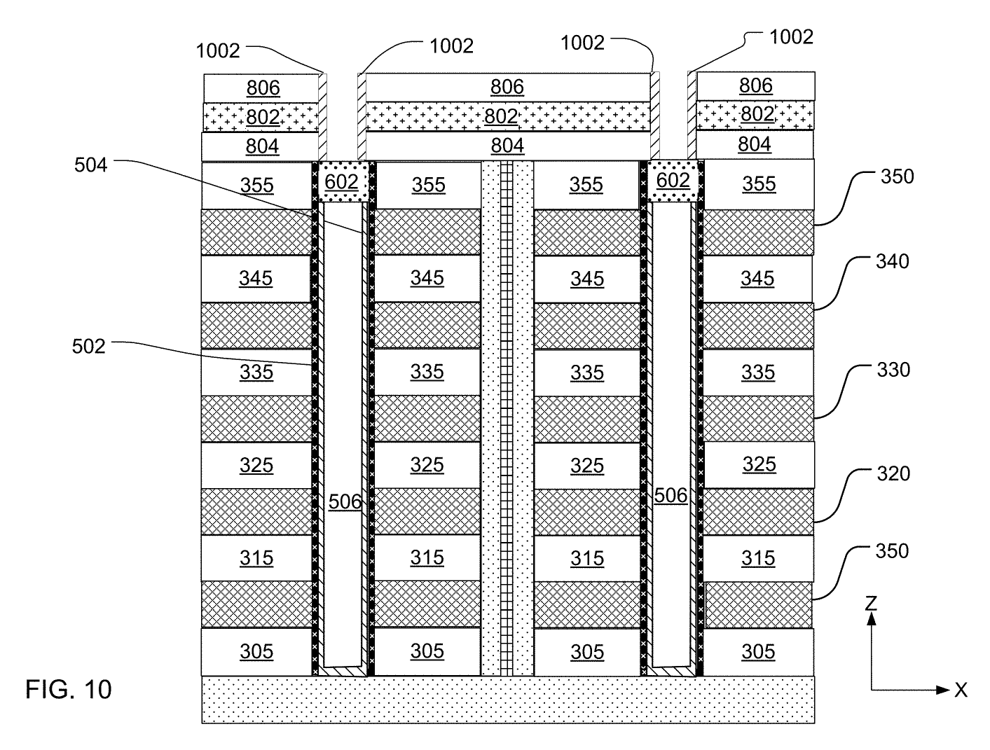

FIG. 10 illustrates a stage in the process flow after performing a step to form gate dielectric layer 1002 on the sidewalls of the conductive strips in the second level 802. The gate dielectric layers 1002 may have a different material composition than the memory layer 502 and cannot trap charges. In some embodiments, the gate dielectric layers 1002 may comprise a high dielectric constant material. In some, the combination of the gate dielectric layers 1002 may have a smaller effective oxide thickness than that of the memory layer 502. The gate dielectric layers 1002 may be formed by depositing a high dielectric constant material inside the second openings 910 and 920. The high dielectric constant material is then etched to form the gate dielectric layers 1002. The gate dielectric layers 1002 expose areas to form second vertical channel structures.

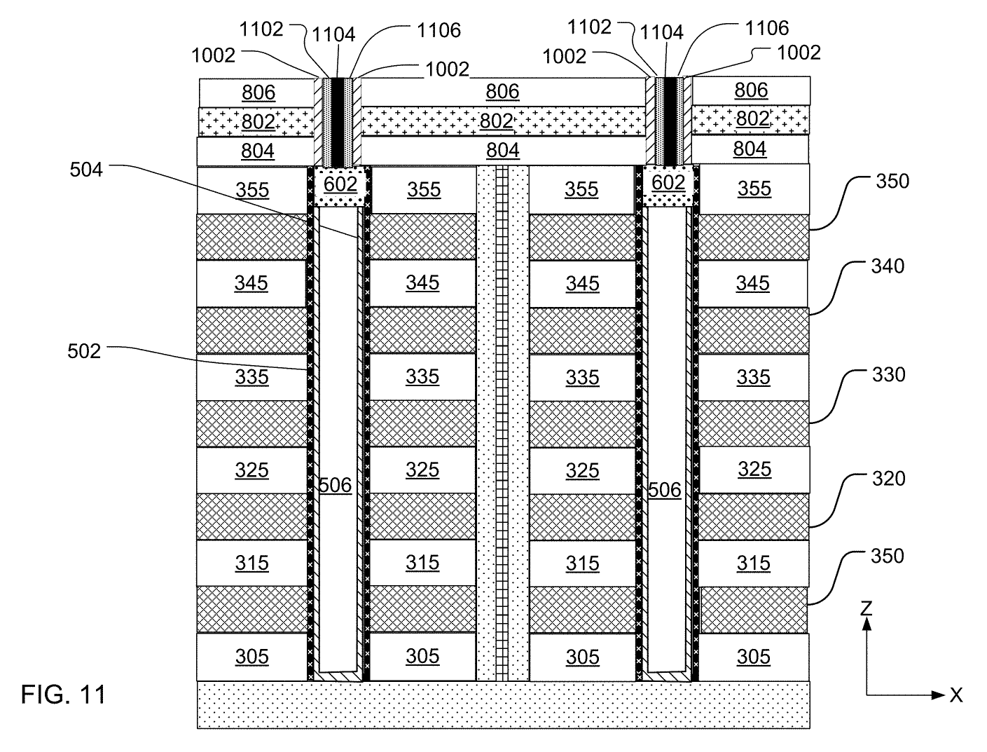

FIG. 11 illustrates a stage in the process flow after performing a step to form second vertical channel structures disposed vertically in contact with the gate dielectric layers 1002 in the second openings. In one embodiment, the second vertical channel structure forms a gate-all-around, vertical MOS transistor. The second vertical channel structures include a cylindrical vertical channel film including sides 1102, 1106, separated by an insulating column 1104. The vertical channel film can comprise semiconductor materials adapted to act as channels, such materials as Si, Ge, SiGe, GaAs, SiC, and graphene. The vertical channel films may be formed by depositing an insulating material inside the second openings. The insulating material is then etched to form spacers between the insulating material and the gate dielectric layers 1002. The etched spacers are then filled with a semiconductor material to form the insulating column 1104 and the vertical channel film.

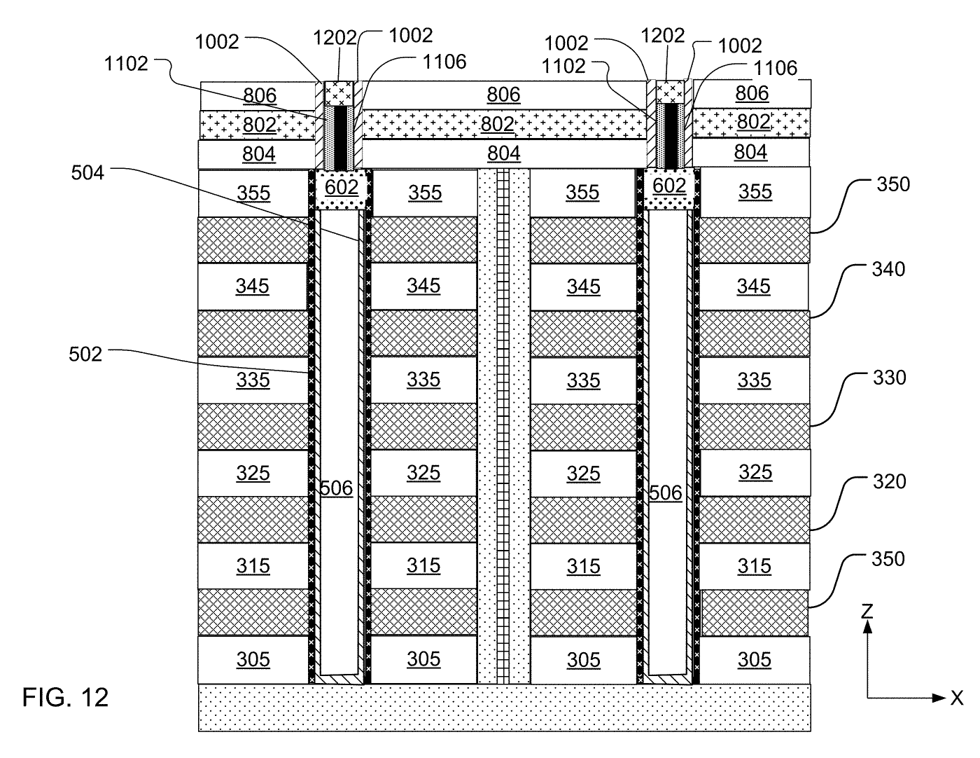

FIG. 12 illustrates a stage in the process flow after performing a step to form second pads 1202. The second vertical channel structure in FIG. 11 is etched to form a recess. A semiconductor material is deposited in the recess to form the second pads 1202. The second pads 1202 can comprise semiconductor materials, such as Si, polysilicon, Ge, SiGe, GaAs, and SiC.

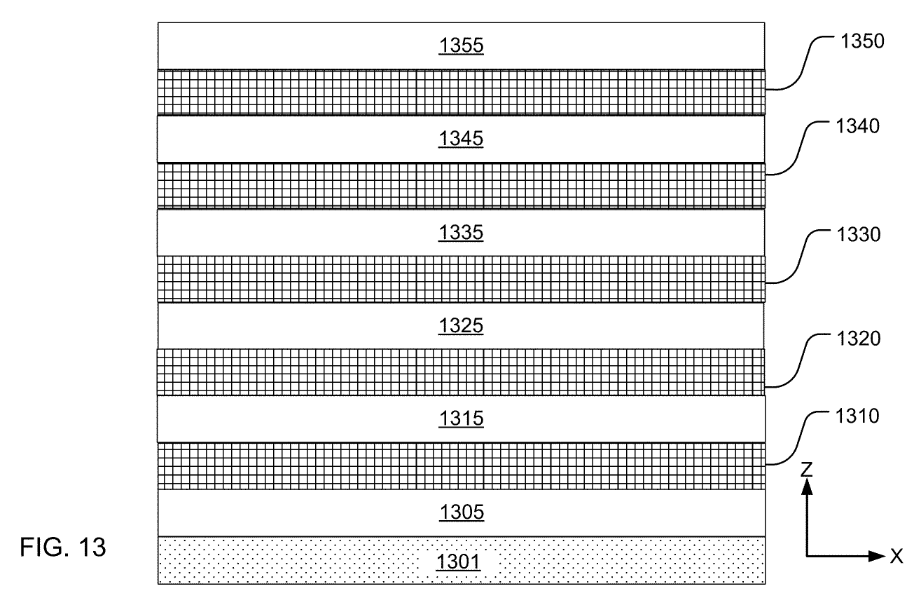

FIGS. 13 through 28 illustrate an example process flow for a 3D memory device with first and second vertical channel structures like that of FIG. 2.

FIG. 13 illustrates a stage of the process flow after forming a plurality of sacrificial layers on top of a conductive layer 1301 which can comprise doped or undoped silicon or another semiconducting material. To form the structure shown in FIG. 13, a plurality of layers 1310, 1320, 1330, 1340, 1350 of a sacrificial material, such as SiN, separated by layers 1355 of insulating material 1305, 1315, 1325, 1335, 1345, are disposed over the conductive layer 1301. The layers of insulating material can comprise silicon dioxide deposited in a variety of ways as known in the art. Also, the layers of insulating material can comprise other insulating materials, and combinations of insulating materials. In this example, all of the insulating layers consist of the same material. In other examples, different materials can be used in different layers as suits a particular design goal. After the plurality of layers is formed, a patterned etch is applied to form a plurality of stacks of conductive strips and first openings.

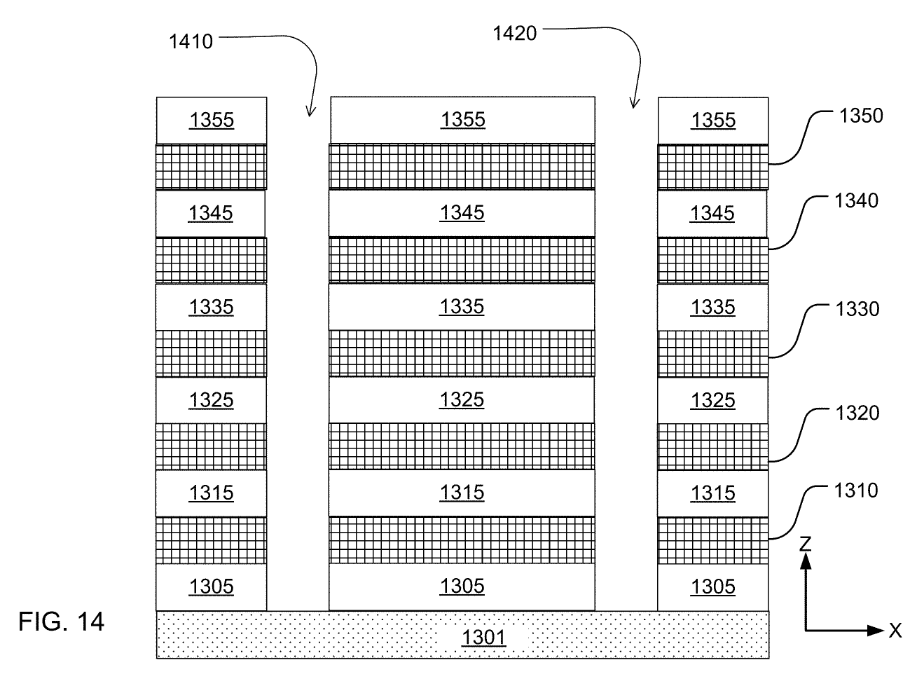

FIG. 14 illustrates a stage of the process after etching the plurality of layers, and stopping below the top surface of the conductive layer 1301 to define a plurality of stacks of sacrificial strips. The stacks include sacrificial strips in a plurality of first levels 1310, 1320, 1330, 1340, 1350. The stacks include layers of insulating material 1305, 1315, 1325, 1335, 1345, 1355 separating the sacrificial strips from one another.

The etching process further defines first openings 1410 and 1420. The opening may be a trench or a hole. For the purpose of this application, a process flow is shown where the etching process defines one or more trenches. However, the technology disclosed herein can also be formed in a hole opening.

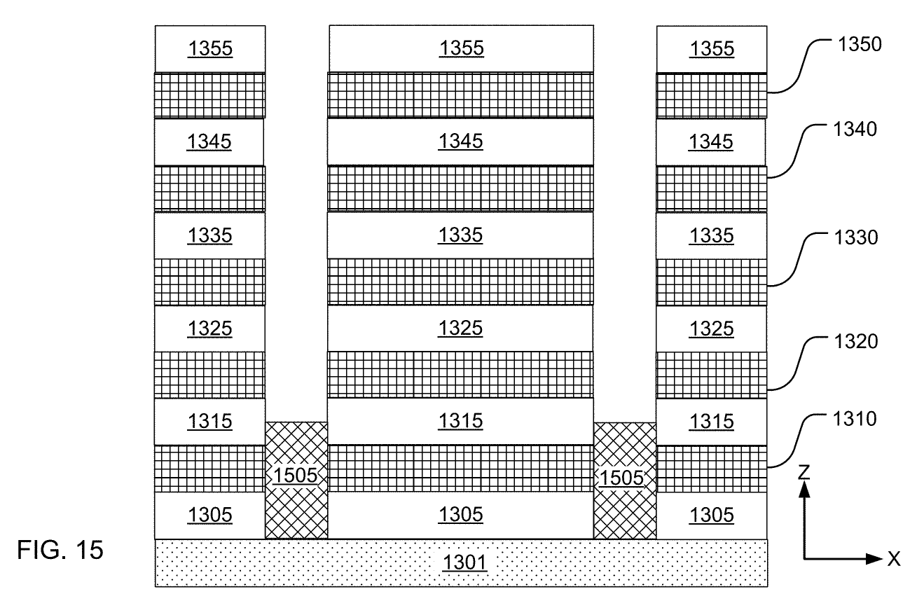

FIG. 15 illustrates a stage in the process after growing semiconductor pads 1505 at the bottom of the first openings 1410 and 1420. The semiconductor pads 1505 are grown through a self-aligned, selective epitaxy of silicon over the conductive layer 1301. Selective epitaxial growth is a technique for epitaxially growing a semiconductor material on a semiconductor substrate in a desired, seeded area. The semiconductor pad 1505 can comprise semiconductor materials, such as Si, polysilicon, Ge, SiGe, GaAs, and SiC.

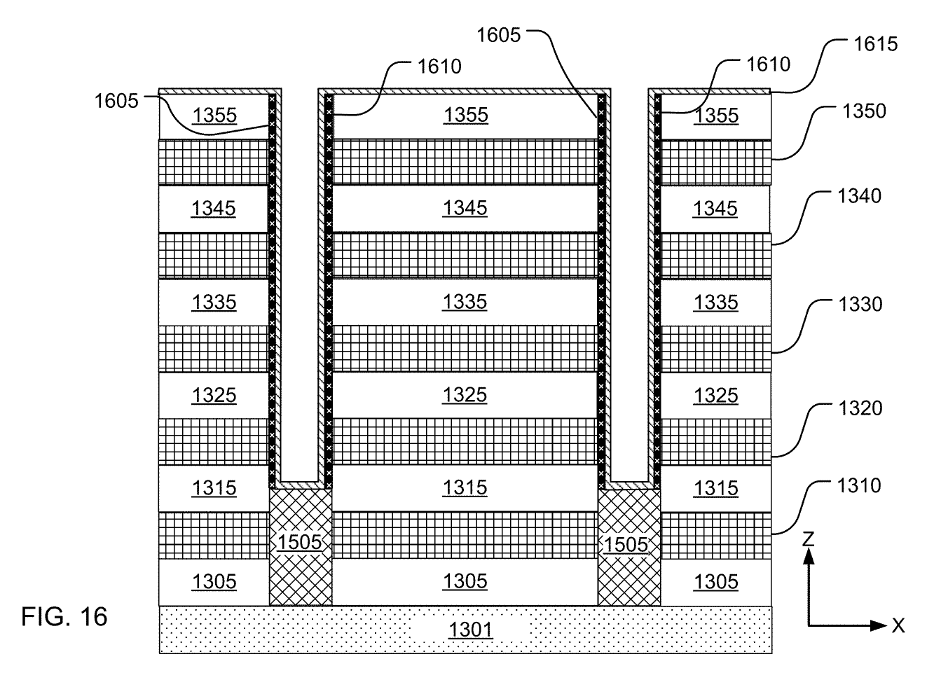

FIG. 16 illustrates a stage of the process flow after forming memory layers 1605, 1610 on sides of conductive strips in the plurality of first levels and a first semiconductor layer 1615. The memory layers 1605, 1610 contact side surfaces of the plurality of sacrificial strips. The memory layer can comprise a multilayer data storage structure including a tunneling layer, a charge storage layer, and a blocking layer, examples of which are discussed above. To form the memory layers 1605, 1610 on sides of conductive strips in the plurality of stacks, a memory structure is formed over and on sides of conductive strips in the plurality of stacks and over the semiconductor pads 1505, and the parts of the memory structure over the stack of sacrificial strips and semiconductor pads are etched. The first semiconductor layer 1615 is formed over the conductive strips in the plurality of first levels and has a surface conformal with the memory layers 1605, 1610. In the dielectric charge storage embodiment, the first semiconductor layer 1615 contacts the memory layers 1605, 1610 at least in the regions in which memory cells are being formed. The semiconductor material in the first semiconductor layer 1615 comprises a semiconductor adapted by choice of material, e.g., silicon, and doping concentrations (e.g., undoped or lightly doped) to act as channel regions for vertical strings of memory cells, at least in the regions between the stacks so as to form channel films on the sidewalls of the opening. As illustrated in FIG. 16, in the regions between the stacks, the first semiconductor layer 1615 extends to the bottom of the openings between the stacks, and overlies the semiconductor pads 1505.

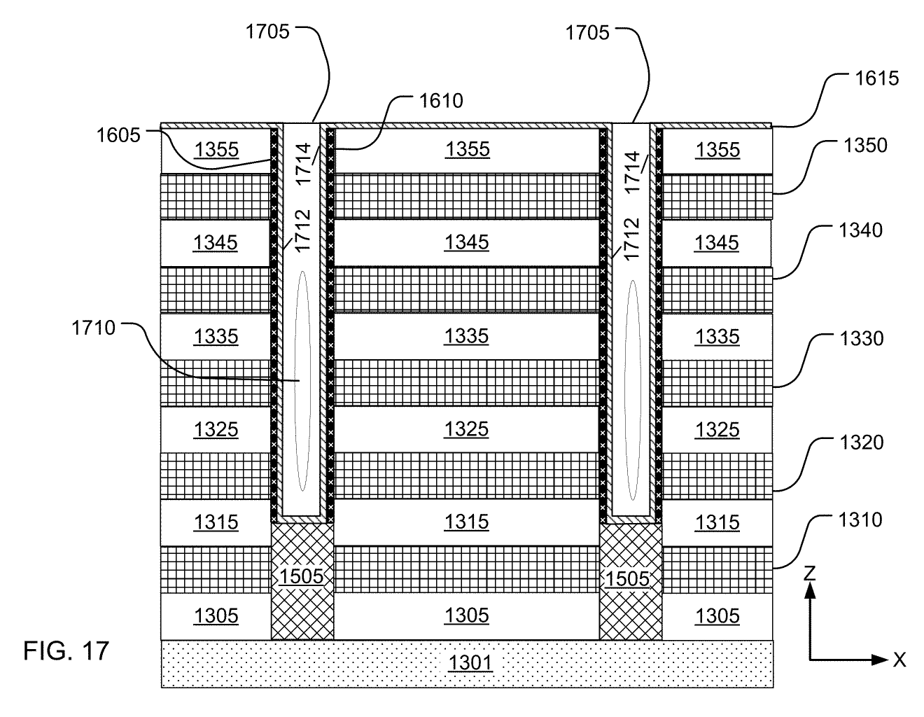

FIG. 17 illustrates a stage in the process flow after performing a step to fill the first openings 1410 and 1420 with an insulating material, such as un-conformal silicon oxide to form first vertical channel structures with sides 1712, 1714. An air gap 1710 may be left at least in regions adjacent to the first vertical channel film sides 1712, 1714. In some embodiments, the first vertical channel structures are cylindrical, and the conductive strips act as a gate-all-around structures surrounding the first vertical channel structures in each frustum of the first vertical channel structures. In some embodiments, the first vertical channel structures are formed in a trench, and the first vertical channel film and second vertical channel film provide channel regions for separate NAND cells on opposing sides of the trench, and the conductive strips act as even and odd word lines for even and odd cells in each frustum of the first vertical channel structures.

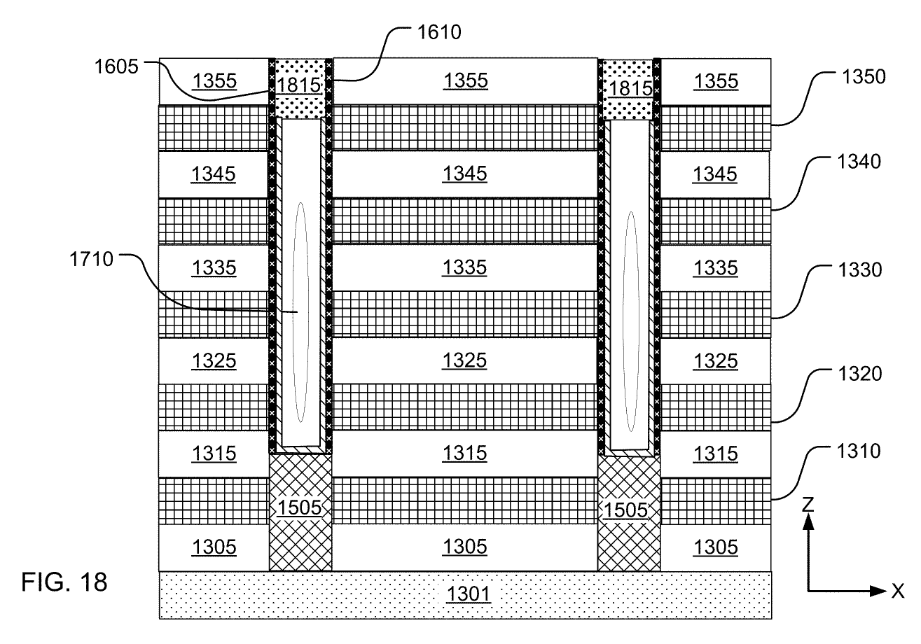

FIG. 18 illustrates a stage in the process flow after performing a step to form first pads 1815. The first semiconductor layer 1615 in FIG. 16 on top of the stacks is planarized, for instance using CMP (chemical-mechanical-planarization), stopping at an insulating material 1355. As un-conformal silicon oxide inside the first vertical channel structures is porous and has a higher etch rate than the etch rate of the insulating material (layer 1355), recesses will be formed on top of the first vertical channel structures. A semiconductor material is deposited in the recesses and on top of the stacks. The deposited semiconductor material on top of the stacks is then planarized, for instance using CMP (chemical-mechanical-planarization), stopping at an insulating material (layer 1355). The recesses are still filled with semiconductor material after the second planarization and form the first pads 1815. The first pads 1815 can comprise semiconductor materials, such as Si, polysilicon, Ge, SiGe, GaAs, and SiC.

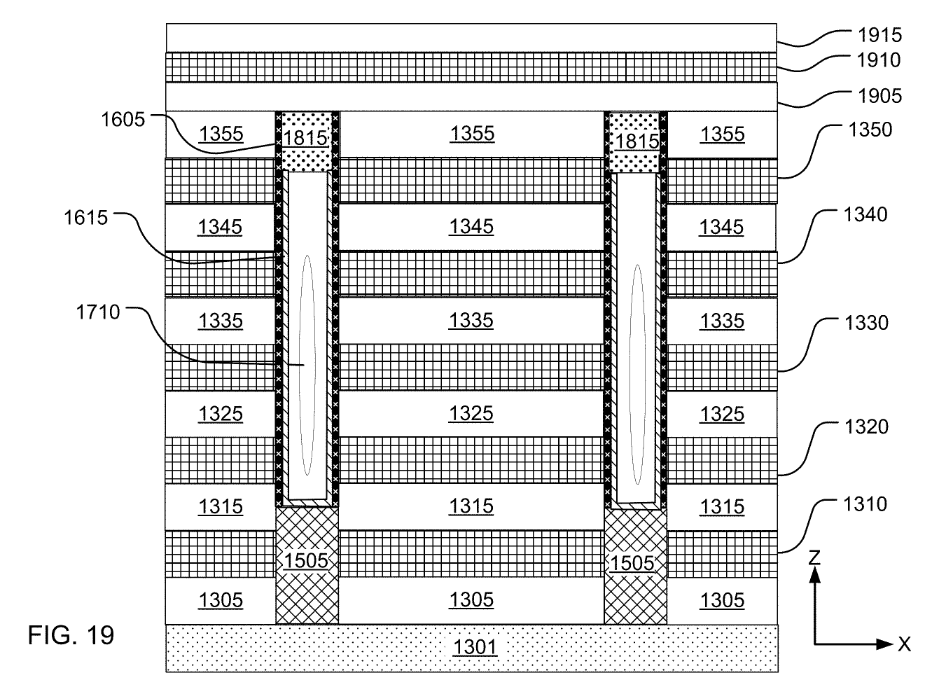

FIG. 19 illustrates a stage of the process flow after forming a sacrificial layer in the second level on top of the structure in FIG. 18. To form the structure shown in FIG. 19, a layer 1910 of a sacrificial material, such as epitaxial or polycrystalline germanium, epitaxial or polycrystalline silicon-germanium, or epitaxial or polycrystalline silicon, separated by layers of insulating material 1905, 1915, are disposed over the first vertical channel structures 506 and the sacrificial strips in the plurality of first levels 1310, 1320, 1330, 1340, 1350. The layers of insulating material 1905, 1915 can comprise silicon dioxide deposited in a variety of ways as known in the art. Also, the layers of insulating material can comprise other insulating materials, and combinations of insulating materials. In this example, all of the insulating layers consist of the same material. In other examples, different materials can be used in different layers as suits a particular design goal. A patterned etch is applied to form a plurality of sacrificial strips in the second level and second openings.

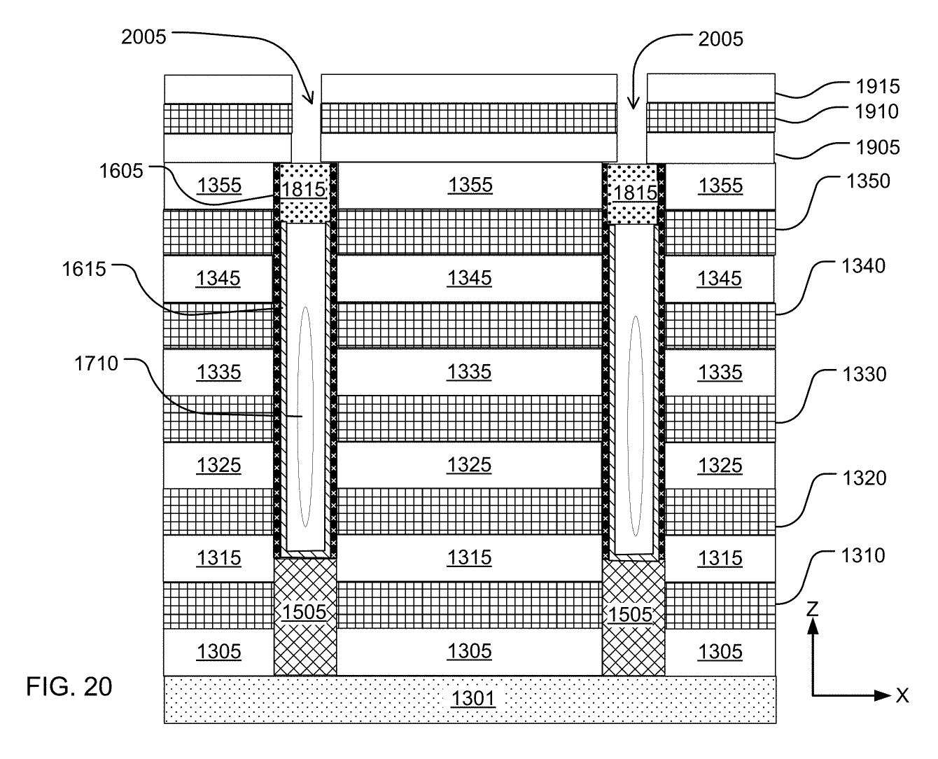

FIG. 20 illustrates a stage of the process after etching layers 1905, 1910, 1915, and stopping below the top surface of the first pads 1815 to define sacrificial strips in the second level 1910. In some embodiments, the sacrificial strips in the second level 1910 may be thicker than the sacrificial strips in a plurality of first levels 1310, 1320, 1330, 1340, 1350. The etching process further defines second openings 2005. The opening may be a trench or a hole. For the purpose of this application, a process flow is shown where the etching process defines one or more trenches. However, the technology disclosed herein can also be formed in a hole opening.

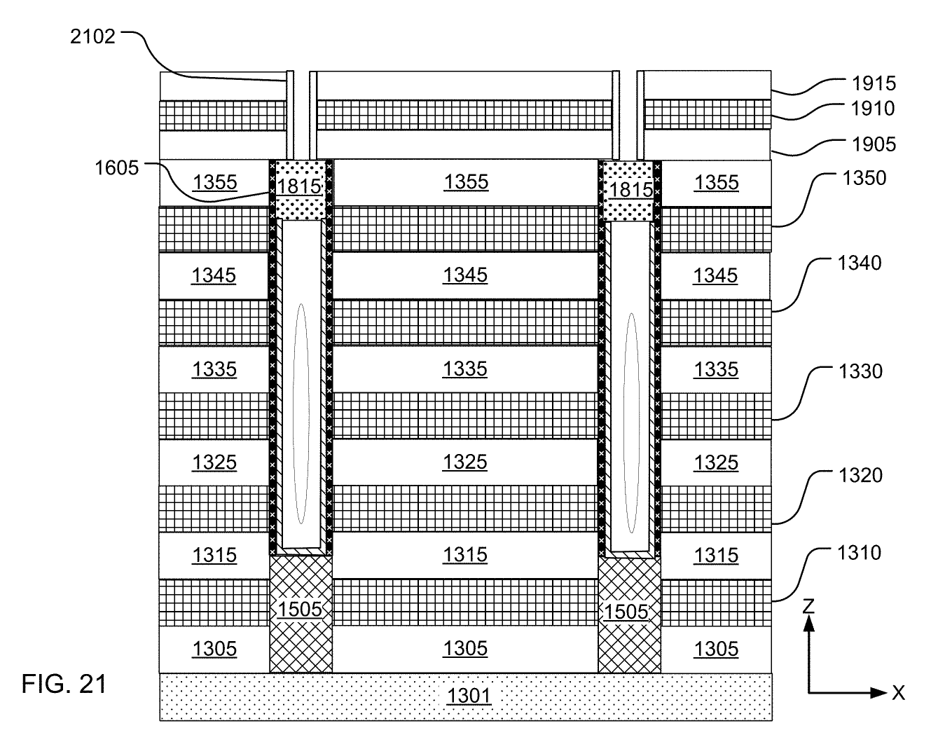

FIG. 21 illustrates a stage in the process flow after performing a step to form gate dielectric layer 2102 on the sidewalls of the sacrificial strips in the second level 1910. The gate dielectric layers 2102 may have a different material composition than the memory layer 1605 and cannot trap charges. In some embodiments, the gate dielectric layers 2102 may comprise a high dielectric constant material. In some, the combination of the gate dielectric layers 2102 may have a smaller effective oxide thickness than that of the memory layer 1605. The gate dielectric layers 2102 may be formed by depositing a high dielectric constant material inside the second openings 2005. The high dielectric constant material is then etched to form the gate dielectric layers 2102. The gate dielectric layers 2102 expose areas to form second vertical channel structures.

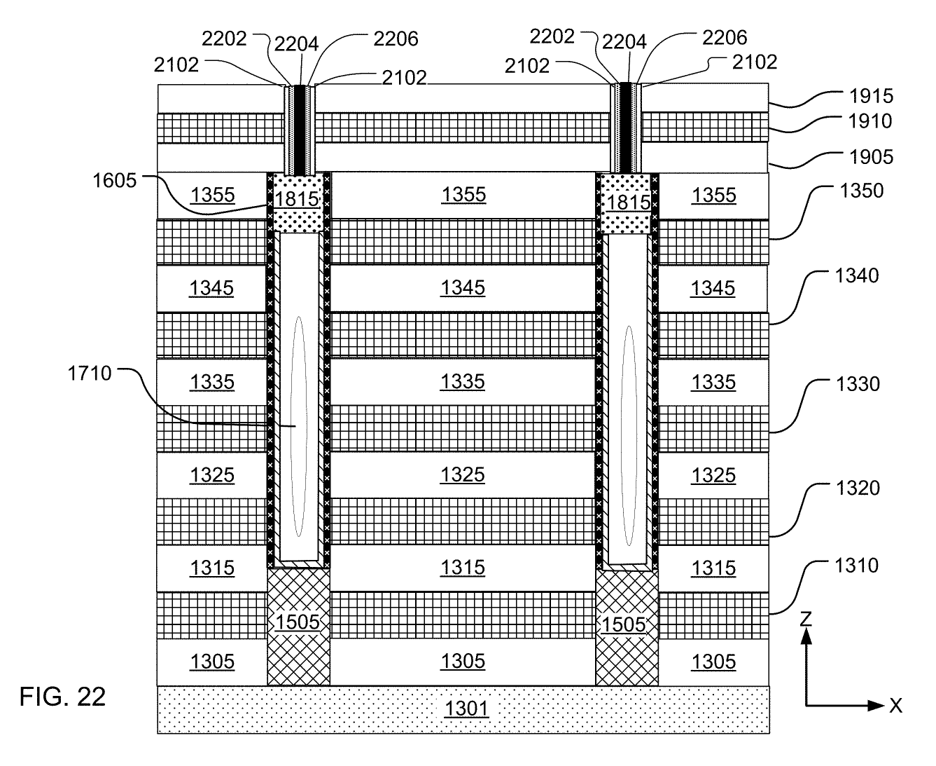

FIG. 22 illustrates a stage in the process flow after performing a step to form second vertical channel structures disposed vertically in contact with the gate dielectric layers 2102 in the second openings. In one embodiment, the second vertical channel structures form gate-all-around, vertical MOS transistors. The second vertical channel structures include a cylindrical vertical channel film including sides 2202, 2206, separated by an insulating column 2204. The vertical channel film can comprise semiconductor materials adapted to act as channels, such materials as Si, Ge, SiGe, GaAs, SiC, and graphene. The vertical channel films may be formed by depositing an insulating material inside the second openings. The insulating material is then etched to form spacers between the insulating material and the gate dielectric layers 2102. The etched spacers are then filled with a semiconductor material to form the insulating column 2204 and the vertical channel film.

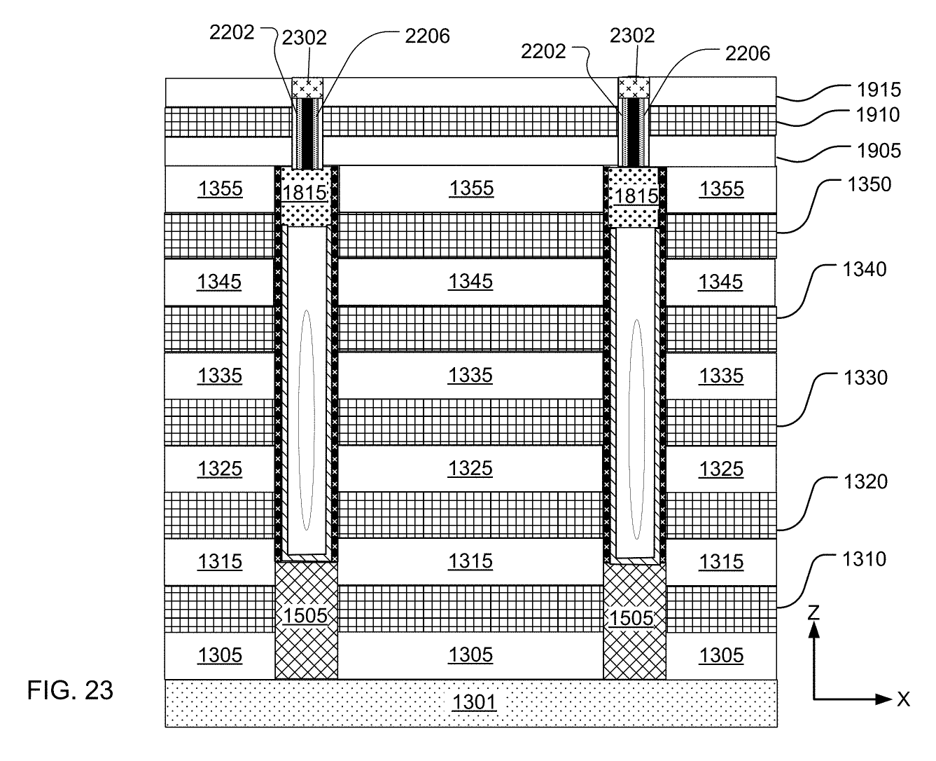

FIG. 23 illustrates a stage in the process flow after performing a step to form second pads 2302. The second vertical channel structures in FIG. 22 are etched to form a recess. A semiconductor material is deposited in the recess to form the second pads 2302. The second pads 2302 can comprise semiconductor materials, such as Si, polysilicon, Ge, SiGe, GaAs, and SiC.

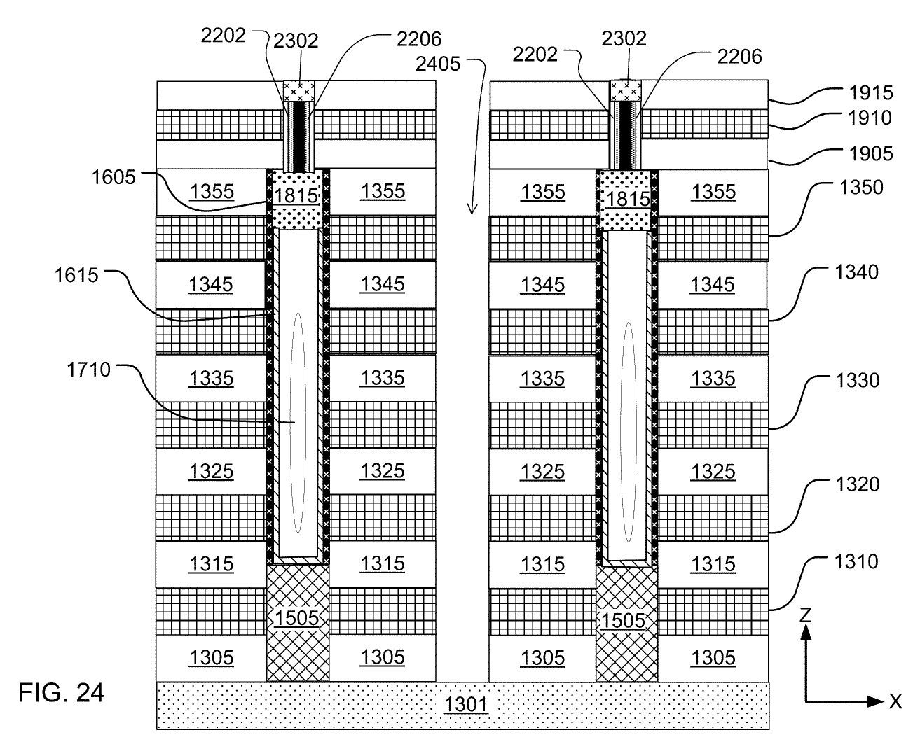

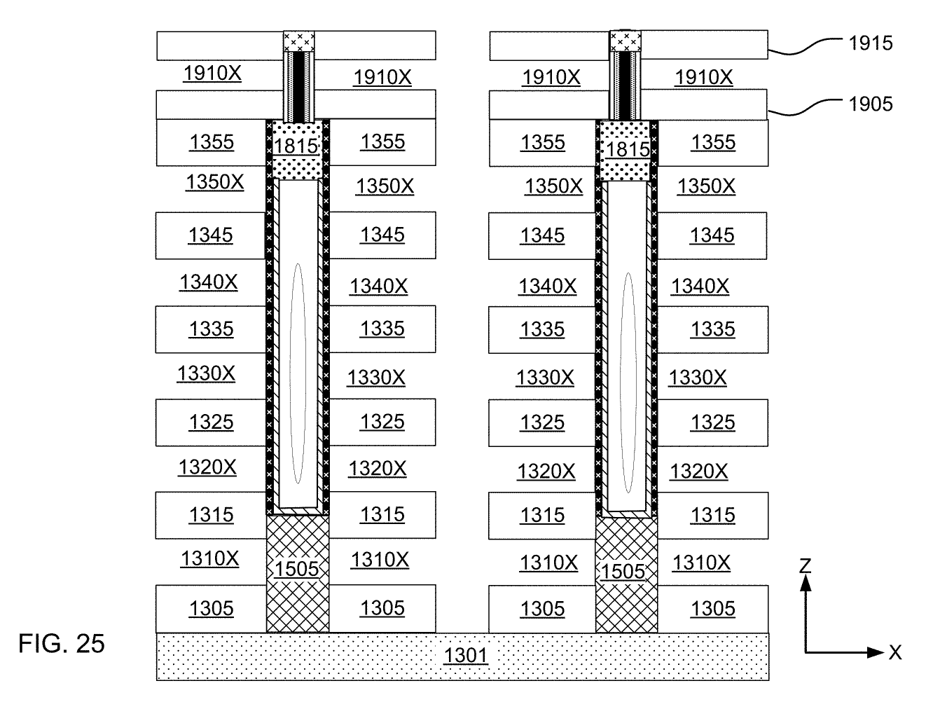

FIG. 24 illustrates a stage in the process after applying a pillar cut etch which includes etching opening 2405 between the first vertical channel structures and the second vertical channel structures. Although the holes in the illustration are rectangular, this is shown for the purposes of the drawing. The holes can be oval or circular or take other shapes as suits a particular etching technology applied. The opening 2405 extends in this example to expose the conductive layer 1301.

FIG. 25 shows the structure after applying a process to selectively remove the sacrificial strips in the stacks to form voids between the insulating strips. Thus, in the stacks in the figure, voids 1310x, 1320x, 1330x, 1340x, 1350x, 1910x are opened after removal of the corresponding sacrificial strips 1310, 1320, 1330, 1340, 1350, 1910, where access for the removal of the sacrificial strips is provided through the opening 2405.

The sacrificial strips can be removed using a selective etch process. For example, etch chemistries suitable for selectively etching SiN with phosphoric acid H₃PO₄. Phosphoric acid is more probable of etching the sacrificial strips 1310, 1320, 1330, 1340, 1350, 1910 than the insulating material 1305, 1315, 1325, 1335, 1345, 1355, and the semiconductor pads 1505.

As a result of the selective etching, the insulating strips (e.g. 1305, 1315, 1325, 1335, 1345, 1355, 1905, 1910) remain suspended between the first vertical channel structures and the second vertical channel structures, with voids allowing access to the selective etch chemistry between the insulating strips in the voids.

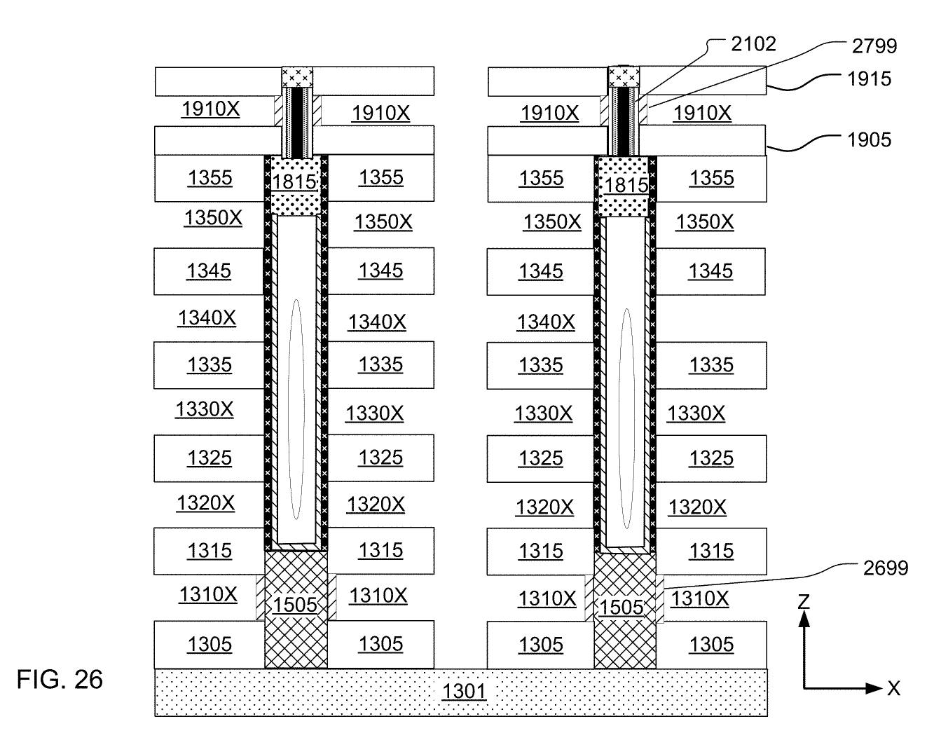

FIG. 26 shows the structure after filling voids 1310x with dielectric liners 2699. The dielectric liners 2699 are formed by oxidization of the exposed surfaces of the semiconductor pads 1505. Dielectric liners 2799 can also be formed in voids 1910X during the surface oxidation process of the semiconductor pads 1505.

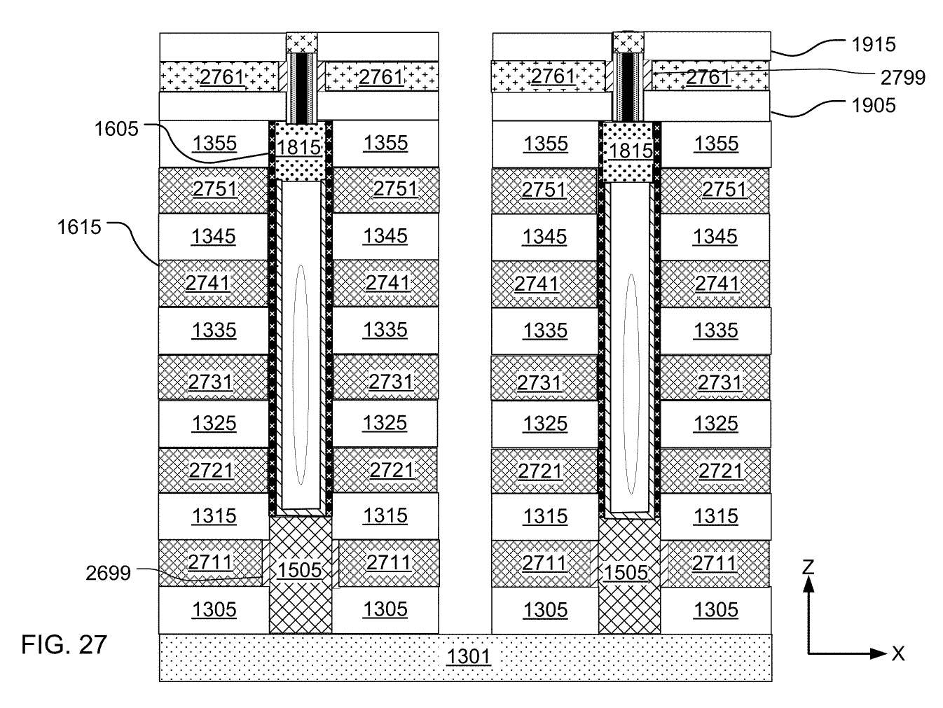

FIG. 27 shows the structure after filling the voids 1310X, 1320X, 1330X, 1340X, 1350X with word line material to be used in the formation of conductive strips in the plurality of first levels 2711, 2721, 2731, 2741, 2751 and filling the voids 1910X with select string line materials to form conductive strips in the second level 2761. The word line material and the string select line material can be deposited using highly conforming chemical vapor deposition or atomic layer deposition. It is optional to deposit one high-κ dielectric liner (not drawn) before filling of conductive strips in the plurality of first levels 2711, 2721, 2731, 2741, 2751 and filling the voids 1910X with select string line materials to form conductive strips in the second level. The high-κ dielectric liner can include high dielectric constant material, having, for example, a dielectric constant κ>7, such as Al₂O₃, HfO₂, ZrO₂, La₂O₃, AlSiO, HfSiO, and ZrSiO, etc., where Al₂O₃ and HfO₂ are preferred in some embodiments. The thickness of the high-κ dielectric liner can be in the range of 0.1 nm to 20 nm in some embodiments. Thicknesses in a range of 2 nm to 5 nm are preferred in some embodiments. A high-κ dielectric liner can be deposited using highly conforming chemical vapor deposition or atomic layer deposition.

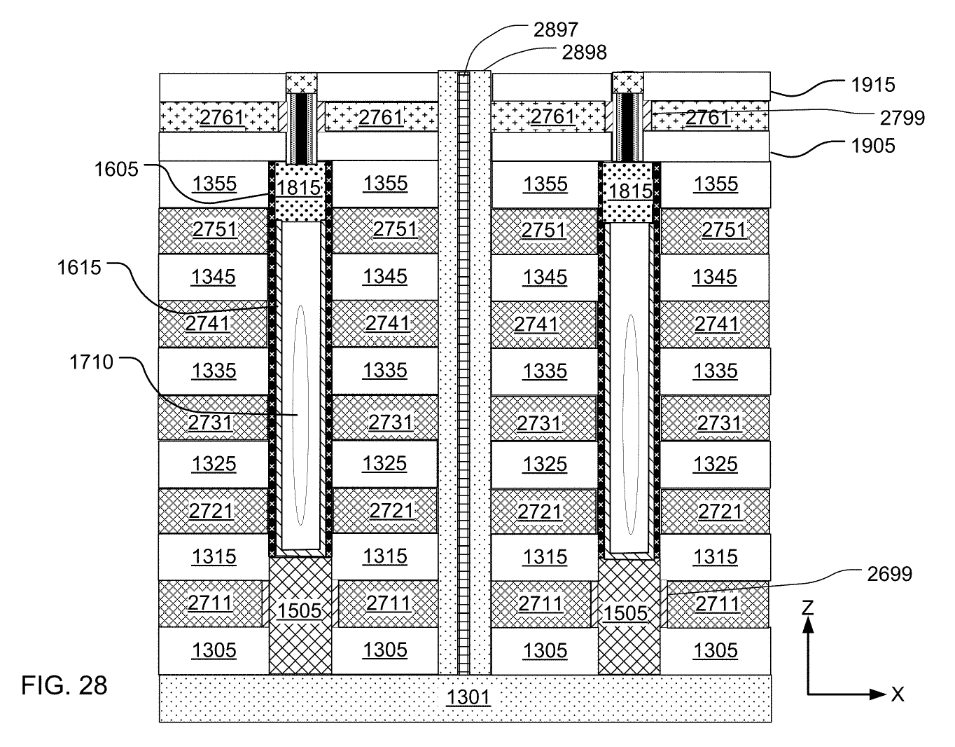

FIG. 28 illustrates a stage in the process flow after performing a step to form a source line 2897 between the two memory devices. The source line can comprise a variety of materials including doped semiconductors, metals, and conductive compounds, including materials comprising Si, Ge, SiGe, SiC, TiN, TaN, W, and Pt. The source line 2898 is separated from the conductive strips in the plurality of first levels 2711, 2721, 2731, 2741, 2751 and conductive strips in the second level 2761 by insulating layers 2898. The source line 2897 and insulating layers 2898 may be formed by etching a first source line opening and then depositing an insulating material inside the first source line opening. A second source line opening is then etched in the deposited insulating material. The second source line opening is then filled with a material selected for compatibility to form the source line 2897.

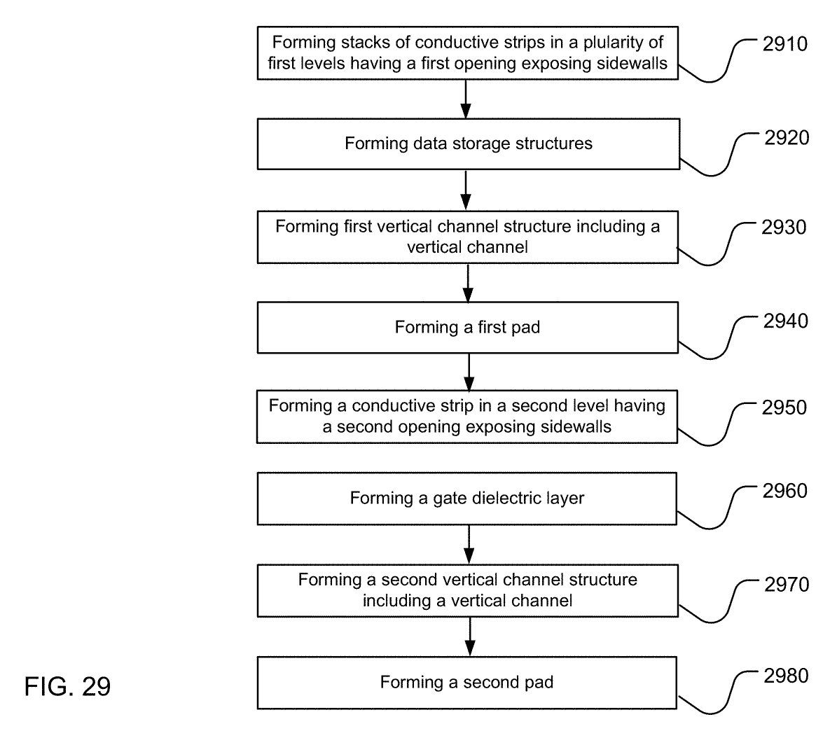

FIG. 29 is a flowchart illustrating a method for manufacturing a 3D memory with first vertical channel structures and second vertical channel structures as described herein. The method includes forming a conductive layer on the substrate by, for example, depositing a layer of silicon, or other dielectric material or combination of materials on the substrate. Over the conductive layer (e.g., 301 in FIGS. 3 and 1301 in FIG. 13), the process includes forming a plurality of layers of a first conductive material in a plurality of first levels, suitable to act as word lines, separated by insulating material, and etching the plurality of layers to define a plurality of stacks (e.g., FIG. 4 and FIG. 14) of conductive strips in the plurality of first levels and a plurality of first openings (step 2910). In some embodiments, conductive strips in the plurality of first levels can also be formed by forming layers of sacrificial material alternating with layers of insulating materials (FIG. 13), forming openings through the layers of sacrificial material to form a stack of sacrificial strips separated by insulating strips (FIG. 24), selectively removing the sacrificial strips in the stack to form voids between the insulating strips (FIG. 25), lining the voids with a dielectric material to form dielectric liners (FIG. 26), and filling the voids with a conductive material to form the conductive strips in the plurality of first levels (FIG. 27).

The method includes forming memory layers (e.g., 502 in FIGS. 5, 1605 and 1610 in FIG. 16) on side surfaces of conductive or sacrificial strips in the plurality of first levels to provide data storage structures (step 2920). The memory layer can comprise a dielectric charge trapping material and are in contact with the side surfaces of the plurality of conductive or sacrificial strips.

The method includes forming first vertical channel structures (e.g., 506 in FIGS. 5 and 1705 in FIG. 17) in the first openings (step 2930). The first vertical channel structures comprise one or more vertical channel films.

The method includes forming first pads (e.g., 602 in FIGS. 6 and 1815 in FIG. 18) in the first openings (step 2940). The first pads are disposed in the first vertical channel structures and connected to the vertical channel films of the first vertical channel structures.

The method includes forming a layer of a second conductive material in the second level, suitable to act as string select lines, separated by insulating material, and etching the conductive layer in the second level to form a plurality of second openings (step 2950). In some embodiments, conductive strips in the second level can also be formed by forming a layer of sacrificial material between layers of insulating materials (FIG. 19), forming an opening through the layer of sacrificial material to form a sacrificial strip between insulating strips (FIG. 24), selectively removing the sacrificial strip to form a void between the insulating strips (FIG. 25), lining the voids with a dielectric material to form dielectric liners (FIG. 26), and filling the voids with a conductive material to form the conductive strips in the second level (FIG. 27).

The method includes forming gate dielectric layers (e.g., 1002 in FIG. 10, 2102 in FIG. 21) on side surfaces of conductive or sacrificial strips in the second level (step 2960). The memory layer can comprise a high dielectric constant material and are in contact with the side surfaces of the plurality of conductive or sacrificial strips in the second level.

The method includes forming second vertical channel structures (e.g., FIG. 11 and FIG. 22) in the second openings (step 2970). The second vertical channel structures comprise one or more vertical channel films.

The method includes forming second pads (e.g., 1202 in FIGS. 12 and 2302 in FIG. 23) in the second openings (step 2980). The second pads are disposed in the second vertical channel structures and connected to the vertical channel films of the second vertical channel structures.

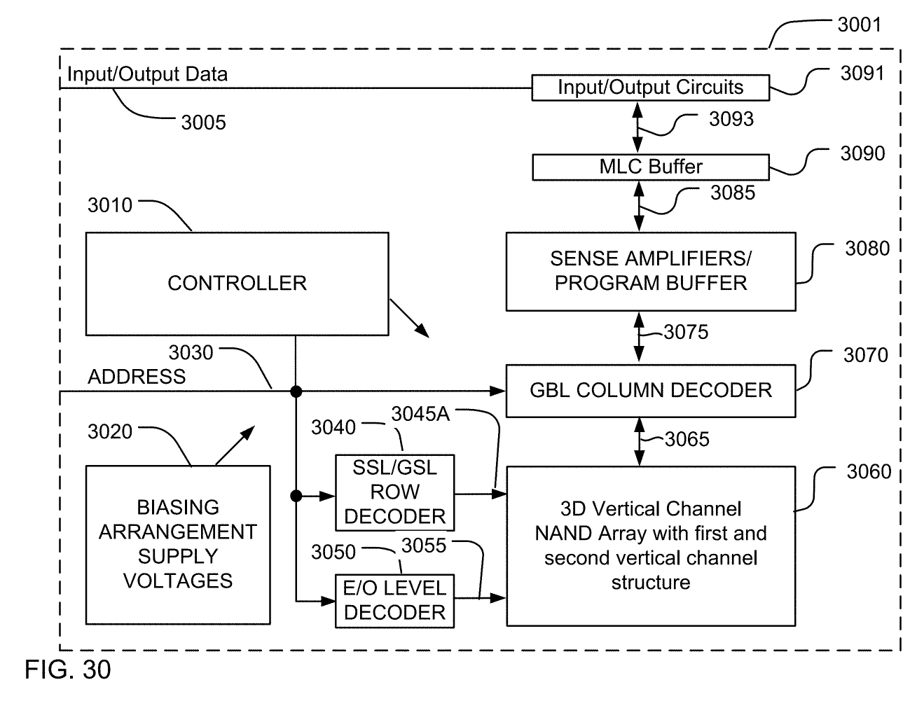

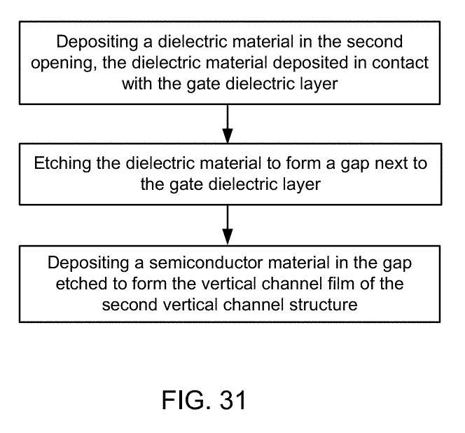

FIG. 30 is a simplified chip block diagram of an integrated circuit 3001 including a 3D NAND array with first and second vertical channel structures. The integrated circuit 3001 includes a memory array 3060 including one or more memory blocks as described herein with first and second vertical channel structures on an integrated circuit substrate.

An SSL/GSL decoder 3040 is coupled to a plurality of SSL/GSL lines 3045A, arranged in the memory array 3060. The plurality of SSL/GSL lines 3045A are further coupled to the second vertical channel structures in the memory blocks in the memory array 3060. A first/second level decoder 3050 is coupled to a plurality of first/second word lines 3055. A global bit line column decoder 3070 is coupled to a plurality of global bit lines 3065 arranged along columns in the memory array 3060 for reading data from and writing data to the memory array 3060. Addresses are supplied on bus 3030 from control logic 3010 to decoder 3070, decoder 3040 and decoder 3050. Sense amplifier and program buffer circuits 3080 are coupled to the column decoder 3070, in this example via first data lines 3075. The program buffer in circuits 3080 can store program data to indicate program or inhibit states for selected bit lines. The column decoder 3070 can include circuits for selectively applying program and inhibit voltages to bit lines in the memory in response to the data values in the program buffer.

Sensed data from the sense amplifier/program buffer circuits are supplied via second data lines 3085 to multi-level data buffer 3090, which is in turn coupled to input/output circuits 3091 via a data path 3093. Also, input data is applied in this example to the multi-level data buffer 3090 for use in support of multiple-level program operations for each of the independent sides of the independent double gate cells in the array.

Input/output circuits 3091 drive the data to destinations external to the integrated circuit 3001. Input/output data and control signals are moved via data bus 3005 between the input/output circuits 3091, the control logic 3010 and input/output ports on the integrated circuit 3001 or other data sources internal or external to the integrated circuit 3001, such as a general purpose processor or special purpose application circuitry, or a combination of modules providing system-on-a-chip functionality supported by the memory array 3060.

In the example shown in FIG. 30, control logic 3010, using a bias arrangement state machine, controls the application of supply voltages generated or provided through the voltage supply or supplies in block 3020, such as read, erase, verify and program bias voltages. The control logic 3010 is coupled to the multi-level data buffer 3090 and the memory array 3060. The control logic 3010 includes logic to control multiple-level program operations. In embodiments supporting the 3D memory described herein, the logic is configured to perform the method of: (i) selecting a layer of memory cells in the array, such as using a word line layer decoder; (ii) selecting a side of the first vertical channel structures in the selected layer such as by selecting a second or first side word line structure; (iii) selecting first vertical channel structures in a selected row in the array such as by using SSL switches and GSL switches on the rows of first vertical channel structures; and (iv) storing charge in charge trapping sites in the selected layer on the selected side of vertical channel structures in one or more selected columns in the array, to represent data using bit line circuitry like page buffers on global bit lines coupled to the selected row of vertical channel structures.

In some embodiments, the logic is configured to select a layer and select a side by selecting one of second and first interdigitated word line structures in the selected layer of the array, such as by controlling second and first word line layer decoders.

In some embodiments, the logic is configured to store multiple levels of charge to represent more than one bit of data in the charge trapping sites in the selected layer on the selected side. In this manner, a selected cell in a selected frustum of a first vertical channel structure in the array stores more than two bits, including more than one bit on each side of the cell. Also, single-bit-per-cell embodiments can include the structures described herein.

The control logic 3010 can be implemented using special-purpose logic circuitry as known in the art. In alternative embodiments, the control logic comprises a general-purpose processor, which can be implemented on the same integrated circuit, which executes a computer program to control the operations of the device. In yet other embodiments, a combination of special-purpose logic circuitry and a general-purpose processor can be utilized for implementation of the control logic.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims. What is claimed is:

1. A memory device, comprising:
a stack of conductive strips having a first opening, the stack of conductive strips including conductive strips having sidewalls in a plurality of first levels;
data storage structures on the sidewalls of the conductive strips on the plurality of first levels;
a first vertical channel structure in the first opening, the first vertical channel structure including a vertical channel film disposed vertically in contact with the data storage structures on the sidewalls of the conductive strips in the plurality of first levels;
a conductive strip in a second level over the conductive strips in the plurality of first levels, the conductive strip in the second level having a second opening aligned with the first vertical channel structure and having a sidewall;
a gate dielectric layer on the sidewall of the conductive strip in the second level;
a second vertical channel structure including a vertical channel film in contact with the gate dielectric layer on the sidewall of the conductive strip in the second level; and
a source line vertically penetrating through the conductive strips in the plurality of first levels and the conductive strip in the second level, the source line being separated from the conductive strips in the plurality of first levels and the conductive strip in the second level by an insulating layer.

2. The memory device of claim 1, further including a first pad connecting the first vertical channel structure to the second vertical channel structure, the first pad contacting the vertical channel film in the first vertical channel structure and the vertical channel film in the second vertical channel structure.

3. The memory device of claim 2, wherein the first pad is disposed inside the first opening and comprises an upper planarized surface in contact with the second vertical channel structure.

4. The memory device of claim 1, further including a second pad disposed inside the second opening, the second pad contacting the vertical channel film in the second vertical channel structure.

5. The memory device of claim 1, wherein the conductive strip in the second level has a thickness greater than the conductive strips in the plurality of first levels.

6. The memory device of claim 1, wherein the conductive strip in the second level comprises a material different than the conductive strips in the plurality of first levels.

7. The memory device of claim 1, wherein the data storage structures comprise a multilayer dielectric charge trapping structure.

8. The memory device of claim 1, wherein the gate dielectric layer has an effective oxide thickness less than that of the data storage structures.

9. The memory device of claim 1, wherein the second vertical channel structure has a width less than that of the first vertical channel structure.

10. A method for manufacturing a memory device, comprising:
forming a stack of conductive strips having a first opening, the stack of conductive strips including conductive strips having sidewalls in a plurality of first levels;
forming data storage structures on the sidewalls of the conductive strips in the plurality of first levels;
forming a first vertical channel structure in the first opening, wherein forming the first vertical channel structure comprises forming a vertical channel film disposed vertically in contact with the data storage structures on the sidewalls of the conductive strips;
forming a conductive strip in a second level over the conductive strips in the plurality of first levels, the conductive strip in the second level having a second opening aligned with the first vertical channel structure and having a sidewall;
forming a gate dielectric layer on the sidewall of the conductive strip in the second level;
forming a second vertical channel structure in the second opening, wherein forming the second vertical channel structure comprises forming a vertical channel film in contact with the gate dielectric layer on the sidewall of the conductive strip in the second level; and
forming a source line vertically penetrating through the conductive strips in the plurality of first levels and the conductive strip in the second level, the source line being separated from the conductive strips in the plurality of first levels and the conductive strip in the second level by an insulating layer, wherein the source line is formed after the second vertical channel structure is formed in the second opening.

11. The method of claim 10, further forming a first pad connecting the first vertical channel structure and the second vertical channel structure, the first pad contacting the vertical channel film in the first vertical channel structure and the vertical channel film in the second vertical channel structure.

12. The method of claim 11, wherein the first pad is disposed inside the first opening and comprises an upper planarized surface in contact with the second vertical channel structure.

13. The method of claim 10, further forming a second pad in the second opening, the second pad in contact the vertical channel film in the second vertical channel structure.

14. The method of claim 10, wherein the conductive strip in the second level has a thickness greater than the conductive strips in the plurality of first levels.

15. The method of claim 10, wherein the conductive strip in the second level comprises a material different than the conductive strips in the plurality of first levels.

16. The method of claim 10, wherein forming the data storage structures comprises forming a multilayer dielectric charge trapping structure.

17. The method of claim 10, wherein forming the stack of conductive strips with the first opening, the stack of conductive strips including conductive strips having sidewalls in the plurality of first levels, comprises:
forming layers of sacrificial material alternating with layers of insulating materials;
forming the first opening through the layers of sacrificial material to form a stack of sacrificial strips separated by insulating strips;
selectively removing the sacrificial strips in the stack to form voids between the insulating strips;
lining at least one of the voids with a dielectric material to form dielectric liners; and
filling the voids with a conductive material to form the conductive strips.

18. The method of claim 10, wherein forming the conductive strip in the second level with the second opening comprises:
forming a layer of sacrificial material between layers of insulating materials;
forming the second opening through the layer of sacrificial material to form a sacrificial strip between insulating strips;
selectively removing the sacrificial strip to form voids between the insulating strips; and
filling the voids with a conductive material to form the conductive strip in the second level.

19. The method of claim 18, wherein forming the gate dielectric layer comprises:
lining the void between the insulating strips with a dielectric material to form the gate dielectric layer after selectively removing the sacrificial strip to form the void.

20. The method of claim 10, wherein forming a second vertical channel structure in the second opening comprises:
depositing a dielectric material in the second opening, the dielectric material deposited in contact with the gate dielectric layer;
etching the dielectric material to form a gap next to the gate dielectric layer; and
depositing a semiconductor material in the gap etched to form the vertical channel film of the second vertical channel structure.
